(19) United States
(12) Patent Application Publication
(10) Pub. No.: US 2024/0244857 A1
(43) Pub. Date: Jul. 18, 2024

(54) ORGANIC COMPOUND, ORGANIC LIGHT EMITTING DIODE AND ORGANIC LIGHT EMITTING DEVICE HAVING THE COMPOUND

(71) Applicant: LG DISPLAY CO., LTD., Seoul (KR)

(72) Inventors: Chi-Ho LEE, Paju-si (KR); Gyeong-Woo KIM, Paju-si (KR); Dong-Ryun LEE, Paju-si (KR); Han-Jin AHN, Paju-si (KR); Jun-Yun KIM, Paju-si (KR)

(73) Assignee: LG DISPLAY CO., LTD., Seoul (KR)

(21) Appl. No.: 18/385,197

(22) Filed: Oct. 30, 2023

(30) Foreign Application Priority Data
Dec. 28, 2022 (KR) 10-2022-0187047

(51) Int. Cl. H10K 50/11; C09K 11/06; H10K 85/30; H10K 85/40; H10K 85/60

(52) U.S. Cl. CPC H10K 50/11; C09K 11/06; H10K 85/346; H10K 85/40; H10K 85/658; C09K 2211/185

(57) ABSTRACT

The present disclosure relates to an organic light emitting diode, and an organic light emitting device including the same. An organic light emitting diode includes a first electrode; a second electrode facing the first electrode; and a first emitting part including a first blue emitting material layer and positioned between the first and second electrodes, the first blue emitting material layer including a first blue emitting layer and a second blue emitting layer, wherein the second blue emitting layer is positioned between the first blue emitting layer and the second electrode, wherein the first blue emitting layer includes a first phosphorescent compound, and the second blue emitting layer includes a second phosphorescent compound and a first fluorescent compound, wherein each of the first and second phosphorescent compounds is represented by Formula 5, and wherein the first fluorescent compound is represented by Formula 7.

### CROSS-REFERENCE TO RELATED APPLICATIONS

The present application claims the benefit of Korean Patent Application No. 10-2022-0187047 filed in the Republic of Korea on Dec. 28, 2022, which is hereby incorporated by reference in its entirety.

### TECHNICAL FIELD

The present disclosure relates to an organic light emitting diode (OLED), and more particularly, to an organic light emitting diode having improved emitting efficiency and color purity and an organic light emitting device including the organic light emitting diode.

### BACKGROUND ART

Requirement for flat panel display devices having small occupied area is increased. Among the flat panel display devices, a technology of an organic light emitting display device, which includes an organic light emitting diode and may be called to as an organic electroluminescent device, is rapidly developed.

The OLED emits light by injecting electrons from a cathode as an electron injection electrode and holes from an anode as a hole injection electrode into an emitting material layer, combining the electrons with the holes, generating an exciton, and transforming the exciton from an excited state to a ground state.

However, the related art OLED has a limitation in the emitting efficiency and the color purity. In particular, there is big limitation in a blue OLED.

### SUMMARY

Accordingly, embodiments of the present disclosure are directed to an OLED and an organic light emitting device that substantially obviate one or more of the problems associated with the limitations and disadvantages of the related art.

An object of the present disclosure is to provide an OLED and an organic light emitting device having and improved emitting efficiency and color purity.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is an organic light emitting diode comprising a first electrode; a second electrode facing the first electrode; and a first emitting part including a first blue emitting material layer and positioned between the first and second electrodes, the first blue emitting material layer including a first blue emitting layer and a second blue emitting layer, wherein the second blue emitting layer is positioned between the first blue emitting layer and the second electrode, wherein the first blue emitting layer includes a first phosphorescent compound, and the second blue emitting layer includes a second phosphorescent compound and a first fluorescent compound, wherein each of the first and second phosphorescent compounds is represented by Formula 5:

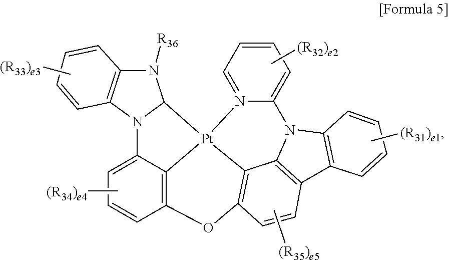

wherein in Formula 5, each of e1, e2 and e3 is independently an integer of 0 to 4, e4 is an integer of 0 to 3, e5 is an integer of 0 to 2, and each of R₃₁ to R₃₆ is independently selected from the group consisting of deuterium, halogen, cyano, a substituted or unsubstituted C1 to C20 alkyl group, a substituted or unsubstituted C3 to C20 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C60 heteroaryl group, wherein the first fluorescent compound is represented by Formula 7:

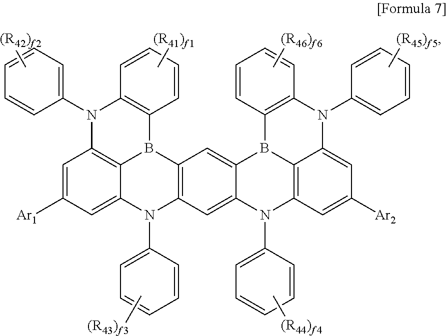

wherein in Formula 7, each of f1 and f6 is independently an integer of 0 to 4, each of f2 to f5 is independently an integer of 0 to 5, each of R₄₁ to R₄₆ is independently selected from the group consisting of deuterium, a substituted or unsubstituted C1 to C10 alkyl group, a substituted or unsubstituted C1 to C10 alkoxy group, a substituted or unsubstituted C6 to C30 arylsilyl group, a substituted or unsubstituted C6 to C30 arylamino group, a substituted or unsubstituted C6 to C30 aryl group and a substituted or unsubstituted C3 to C60 heteroaryl group, and each of Ar₁ and Ar₂ is independently selected from the group consisting of a substituted or unsubstituted C6 to C30 arylamino group, a substituted or unsubstituted C6 to C30 aryl group and a substituted or unsubstituted C3 to C60 heteroaryl group.

Another aspect of the present disclosure is an organic light emitting device comprising a substrate; the above organic light emitting diode disposed over the substrate; and an encapsulation layer covering the organic light emitting diode.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device of the present disclosure.

FIG. 2 is a schematic cross-sectional view of an organic light emitting display device according to a first embodiment of the present disclosure.

FIG. 3 is a schematic cross-sectional view of an OLED according to a second embodiment of the present disclosure.

FIG. 4 is a schematic cross-sectional view of an OLED according to a third embodiment of the present disclosure.

FIG. 5 is a schematic cross-sectional view of an OLED according to a fourth embodiment of the present disclosure.

FIG. 6 is a schematic cross-sectional view of an OLED according to a fifth embodiment of the present disclosure.

FIG. 7 is a schematic cross-sectional view of an organic light emitting display device according to a sixth embodiment of the present disclosure.

FIG. 8 is a schematic cross-sectional view of an organic light emitting display device according to a seventh embodiment of the present disclosure.

FIG. 9 is a schematic cross-sectional view of an OLED according to an eighth embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When “including,” “having,” “consisting,” and the like are used in this specification, other parts may be added unless “only” is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Reference will now be made in detail to some of the examples and preferred embodiments, which are illustrated in the accompanying drawings.

The present disclosure relates to an OLED, in which each of adjacent blue emitting layers has different combination in their compounds (materials), and an organic light emitting device including the OLED. For example, an organic light emitting device may be an organic light emitting display device or an organic lightening device. As an example, an organic light emitting display device, which is a display device including the OLED of the present disclosure, will be mainly described.

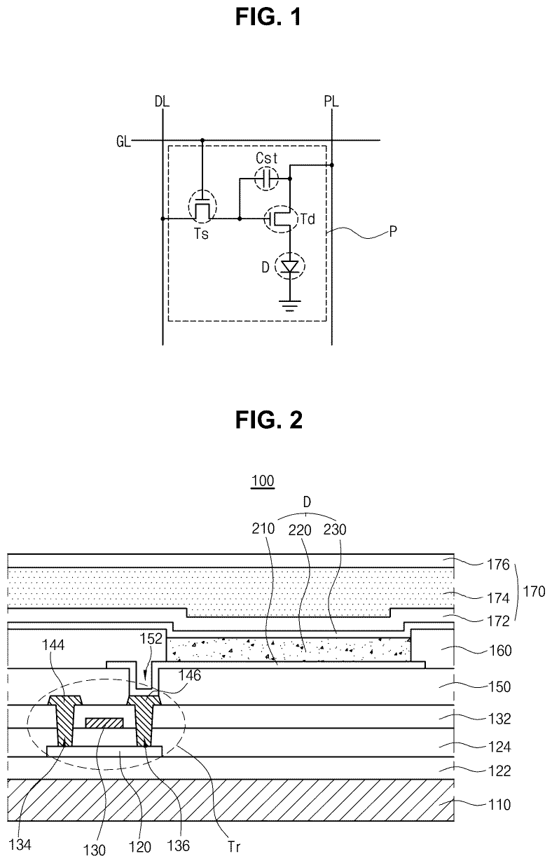

FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region may include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr on or over the substrate 110, a planarization layer 150 covering the TFT Tr and an OLED D on the planarization layer 150 and connected to the TFT Tr. A red pixel region, a green pixel region and a blue pixel region may be defined on the substrate 110.

The substrate 110 may be a glass substrate or a flexible substrate. For example, the flexible substrate may be one of a polyimide (PI) substrate, a polyethersulfone (PES) substrate, a polyethylenenaphthalate (PEN) substrate, a polyethylene terephthalate (PET) substrate and a polycarbonate (PC) substrate.

A buffer layer 122 is formed on the substrate, and the TFT Tr is formed on the buffer layer 122. The buffer layer 122 may be omitted. For example, the buffer layer 122 may be formed of an inorganic insulating material, e.g., silicon oxide or silicon nitride.

A semiconductor layer 120 is formed on the buffer layer 122. The semiconductor layer 120 may include an oxide semiconductor material or polycrystalline silicon.

When the semiconductor layer 120 includes the oxide semiconductor material, a light-shielding pattern (not shown) may be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities may be doped into both sides of the semiconductor layer 120.

A gate insulating layer 124 is formed on the semiconductor layer 120. The gate insulating layer 124 may be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120. In FIG. 2, the gate insulating layer 124 is formed on an entire surface of the substrate 110. Alternatively, the gate insulating layer 124 may be patterned to have the same shape as the gate electrode 130.

An interlayer insulating layer 132 is formed on the gate electrode 130 and over an entire surface of the substrate 110. The interlayer insulating layer 132 may be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first and second contact holes 134 and 136 are formed through the gate insulating layer 124 and the interlayer insulating layer 132. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132.

The source electrode 144 and the drain electrode 146 are spaced apart from each other with respect to the gate electrode 130 and respectively contact both sides of the semiconductor layer 120 through the first and second contact holes 134 and 136.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure.

Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element. In addition, the power line, which may be formed to be parallel to and spaced apart from one of the gate and data lines, and the storage capacitor for maintaining the voltage of the gate electrode of the TFT Tr in one frame may be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr.

The OLED D is disposed on the planarization layer 150 and includes a first electrode 210, which is connected to the drain electrode 146 of the TFT Tr, an organic light emitting layer 220 and a second electrode 230. The organic light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 may be an anode and may include a transparent conductive oxide material layer, which may be formed of a conductive material, e.g., a transparent conductive oxide (TCO), having a relatively high work function.

For example, the transparent conductive oxide material layer may be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

The first electrode 210 may have a single-layered structure of the transparent conductive oxide material layer. Namely, the first electrode 210 may be a transparent electrode.

Alternatively, the first electrode 210 may further include a reflective layer to have a double-layered structure or a triple-layered structure. Namely, the first electrode 210 may be a reflective electrode.

For example, the reflective layer may be formed of one of silver (Ag), an alloy of Ag and one of palladium (Pd), copper (Cu), indium (In) and neodymium (Nd), and aluminum-palladium-copper (APC) alloy. For example, the first electrode 210 may have a double-layered structure of Ag/ITO or APC/ITO or a triple-layered structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 including an emitting material layer (EML) is formed on the first electrode 210. In the OLED D in the blue pixel region, the EML of the organic light emitting layer 220 includes a first blue emitting layer and a second blue emitting layer.

The organic light emitting layer 220 may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

In an aspect of the present disclosure, the organic light emitting layer 220 of the OLED D in the blue pixel region may include a first blue emitting part including a first blue EML and a second blue emitting part including a second blue EML to have a tandem structure, and at least one of the first and second blue EMLs may include a first blue emitting layer and a second blue emitting layer. In this case, the organic light emitting layer 220 may further include a charge generation layer (CGL) between the first and second blue emitting parts.

As described below, in the OLED D of the blue pixel region, the first blue emitting layer, which is closer to the first electrode as anode, includes a phosphorescent compound, and the second blue emitting layer, which is closer to the second electrode as a cathode, includes a phosphorescent compound and a fluorescent compound. As a result, the OLED D and the organic light emitting display device 100 of the present disclosure have improved emitting efficiency and color purity.

The second electrode 230 is formed over the substrate 110 where the organic light emitting layer 220 is formed. The second electrode 230 covers an entire surface of the display area and may be formed of a conductive material having a relatively low work function to serve as a cathode. For example, the second electrode 230 may be formed of aluminum (Al), magnesium (Mg), calcium (Ca), silver (Ag) or their alloy, e.g., Mg—Ag alloy (Mg:Ag).

In a top-emission type OLED D, the first electrode 210 serves as a reflective electrode, and the second electrode 230 has a light transparent (or semi-transparent) property. Alternatively, in a bottom-emission type OLED, the first electrode 210 serves as a transparent electrode, and the second electrode serves as a reflective electrode. In the bottom-emission type OLED D, the second electrode 220 may be formed of Al. In the top-emission type OLED D, the second electrode 220 may be formed of Mg:Ag. In this case, a weight % ratio of Mg to Ag may be in a range of 1:9 to 9:1, preferably 1:9 to 3:7.

A top-emission type OLED D may further include a capping layer on the second electrode 230. The emitting efficiency of the OLED D and the organic light emitting display device 100 may be further improved by the capping layer.

An encapsulation layer (or an encapsulation film) 170 is formed on the second electrode 230 to prevent penetration of moisture into the OLED D. The encapsulation layer 170 includes a first inorganic insulating layer 172, an organic insulating layer 174 and a second inorganic insulating layer 176 sequentially stacked, but it is not limited thereto.

Although not shown, the organic light emitting display device 100 may include a color filter layer corresponding to the red, green and blue pixel regions. For example, the color filter layer may be positioned on or over the OLED D or between the substrate 110 and the OLED D. In the top-emission type organic light emitting display device 100, the color filter layer may be formed on the encapsulation layer 170.

The organic light emitting display device 100 may further include a polarization plate for reducing an ambient light reflection. For example, the polarization plate may be a circular polarization plate. In the bottom-emission type organic light emitting display device 100, the polarization plate may be disposed under the substrate 110. In the top-emission type organic light emitting display device 100, the polarization plate may be disposed on or over the encapsulation layer 170.

In addition, the organic light emitting display device 100 may further include a cover window on or over the encapsulation layer 170 or the polarization plate. In this instance, the substrate 110 and the cover window have a flexible property such that a flexible organic light emitting display device may be provided.

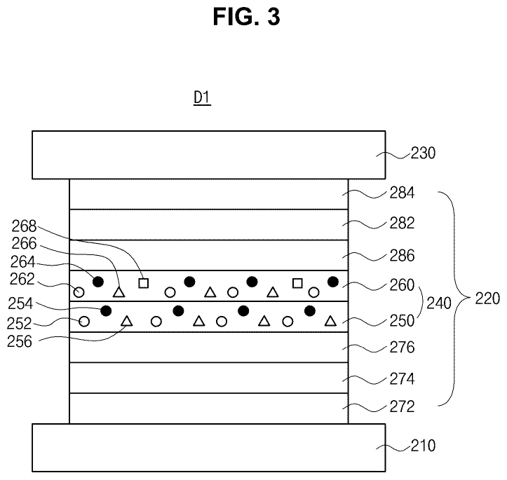

FIG. 3 is a schematic cross-sectional view of an OLED according to a second embodiment of the present disclosure.

As shown in FIG. 3, the OLED D1 includes first and second electrodes 210 and 230, which face each other, and an organic light emitting layer 220 therebetween. The organic light emitting layer 220 includes a blue emitting material layer (EML) 240, and the blue EML 240 includes a first blue emitting layer 250 and a second blue emitting layer 260. The OLED D1, which is a top-emission type, may further include a capping layer on the second electrode 230 to enhance a light extraction efficiency.

The organic light emitting display device 100 (of FIG. 2) may include a red pixel region, a green pixel region and a blue pixel region, and the OLED D1 may be positioned in the blue pixel region.

The first electrode 210 is an anode, and the second electrode 230 is a cathode. One of the first and second electrodes 210 and 230 may be a reflective electrode, and the other one of the first and second electrodes 210 and 230 may be a transparent (or a semi-transparent) electrode.

In a top-emission type OLED D1, the first electrode 210 may be a reflective electrode and may have a structure of ITO/Ag/ITO, and the second electrode 230 may be a transparent electrode and may be formed of Mg:Ag with a weight % ratio of 1:9.

In a bottom-emission type OLED D1, the first electrode 210 may be a transparent electrode and may be formed of ITO, and the second electrode 230 may be a reflective electrode and may be formed of Al.

In the blue EML 240, the second blue emitting layer 260 contacts and is disposed on the first blue emitting layer 250 so that the blue EML 240 has a double-layered structure. The first blue emitting layer 250 is disposed to be closer to the first electrode 210 as an anode than the second blue emitting 260, and the second blue emitting layer 260 is disposed to be closer to the second electrode 230 as a cathode than the first blue emitting layer 250.

The first blue emitting layer 250 includes a first phosphorescent compound 256. In addition, the first blue emitting layer 250 may further include a first p-type host 252 and a first n-type host 254. The first blue emitting layer 250 is a phosphorescent emitting layer.

The first phosphorescent compound 256 serves as an emitter (e.g., dopant) so that the blue light is provided (emitted) from the first phosphorescent compound 256. An exciplex can be generated by the first p-type host 252 and the first n-type host 254.

The second blue emitting layer 260 includes a second phosphorescent compound 266 and a fluorescent compound 268. In addition, the second blue emitting layer 260 may further include a second p-type host 262 and a second n-type host 264. The second blue emitting layer 260 is a phosphor-sensitized fluorescence (PSF) emitting layer.

The fluorescent compound 268 serves as an emitter (e.g., dopant) so that the blue light is provided (emitted) from the fluorescent compound 268. An energy may be transferred into the fluorescent compound 268 by the second phosphorescent compound 266. The second phosphorescent compound 266 may be referred to as an auxiliary dopant or auxiliary host. An exciplex can be generated by the second p-type host 262 and the second n-type host 264.

Each of the first p-type host 252 in the first blue emitting layer 250 and the second p-type host 262 in the second blue emitting layer 260 is represented by Formula 1.

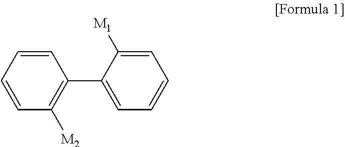

In Formula 1, each of M₁ and M₂ is independently selected from Formula 1a, Formula 1b and Formula 1c.

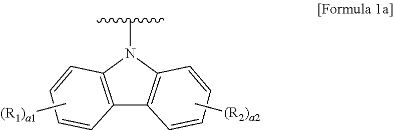

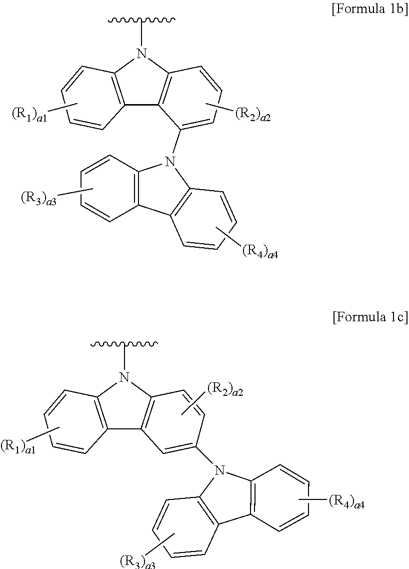

In Formulas 1a, 1b and 1c, each of a1, a3 and a4 is independently an integer of 0 to 4, a2 is an integer of 0 to 3, and

each of R1 to R4 is independently selected from the group consisting of a substituted or unsubstituted C6 to C30 arylsilyl group, a substituted or unsubstituted C6 to C30 aryl group and a substituted or unsubstituted C3 to C60 heteroaryl group.

In the present disclosure, without specific definition, a substituent of an arylsilyl group, an alkyl group, an aryl group, a heteroaryl group, an arylamino group may be selected from deuterium, halogen, cyano, a substituted or unsubstituted C6 to C30 arylsilyl group, a substituted or unsubstituted C1 to C20 alkyl group and a substituted or unsubstituted C6 to C30 aryl group.

In the present disclosure, without specific definition, a C1 to C20 alkyl group or a C1 to C10 alkyl group may be selected from the group consisting of methyl, ethyl, propyl and butyl, e.g., n-butyl or tert-butyl.

In the present disclosure, without specific definition, a C3 to C20 cycloalkyl group may be selected from the group consisting of cyclopropyl, cyclobutyl, cyclohexyl and adamantanyl.

In the present disclosure, without specific definition, a C6 to C30 arylsilyl group may be triphenylsilyl. In the present disclosure, without specific definition, a C6 to C60 arylamino group may include a C6 to C30 arylamino group, e.g., diphenylamino.

In the present disclosure, without specific definition, a C6 to C30 aryl group may include a C6 to C20 aryl group, and may be selected from the group consisting of phenyl, biphenyl, terphenyl, naphthyl, anthracenyl, pentalenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C3 to C60 heteroaryl group may include a C3 to C30 heteroaryl group or a C3 to C20 heteroaryl group, and may be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, quinolinyl, purinyl, phthalazinyl, quinoxalinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In Formula 1, when at least one of a1 to a4 is a positive integer, at least one of R₁ to R₄ each occurrence may be a substituted or unsubstituted C6 to C30 arylsilyl group, e.g., triphenylsilyl.

For example, each of the first p-type host 252 and the second p-type host 262 may be independently selected from compounds in Formula 2. The first p-type host 252 and the second p-type host 262 may be same or different.

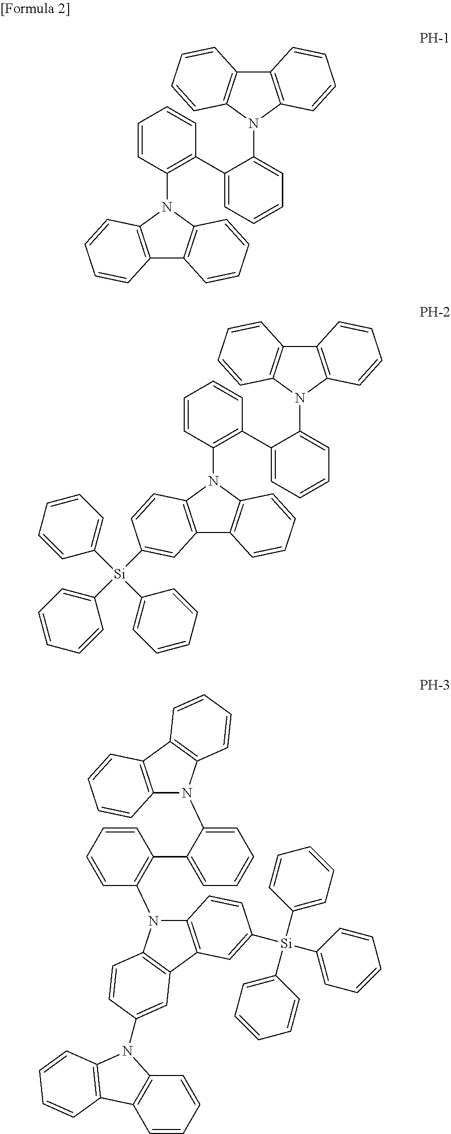 [SMILES: c1ccc(-n2c3ccccc3c3ccccc32)c(-c2ccccc2-n2c3ccccc3c3ccccc32)c1 ; c1ccc([Si](c2ccccc2)(c2ccccc2)c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2cc(-n4c5ccccc5c5ccccc54)ccc2n3-c2ccccc2-c2ccccc2-n2c3ccccc3c3ccccc32)cc1]

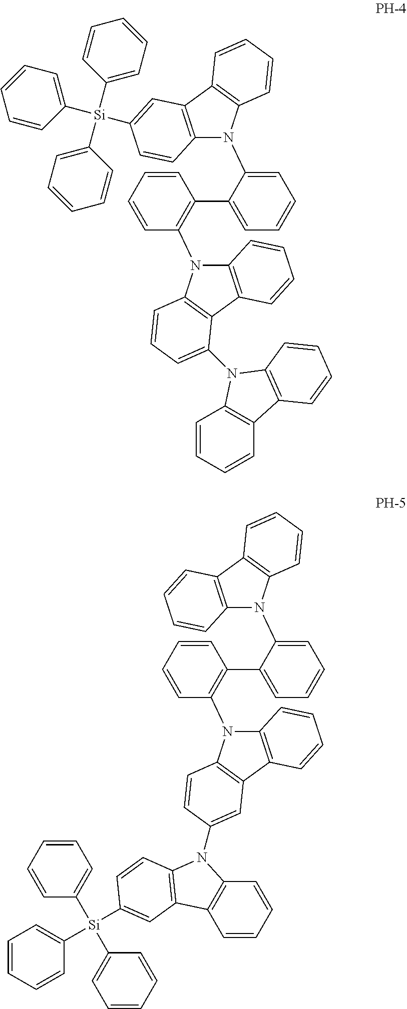 [SMILES: c1ccc([Si](c2ccccc2)(c2ccccc2)c2ccc3c(c2)c2ccccc2n3-c2ccccc2-c2ccccc2-n2c3ccccc3c3c(-n4c5ccccc5c5ccccc54)cccc32)cc1 ; c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1]

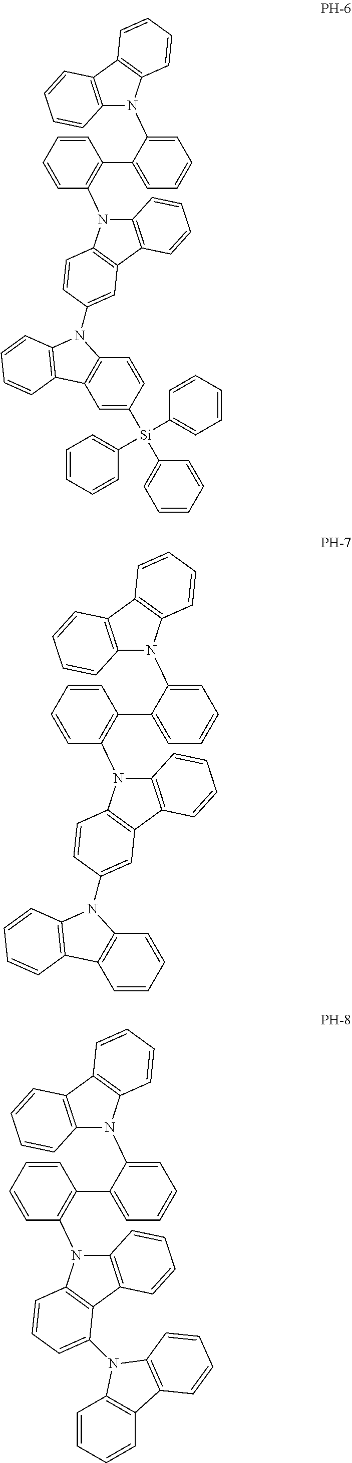

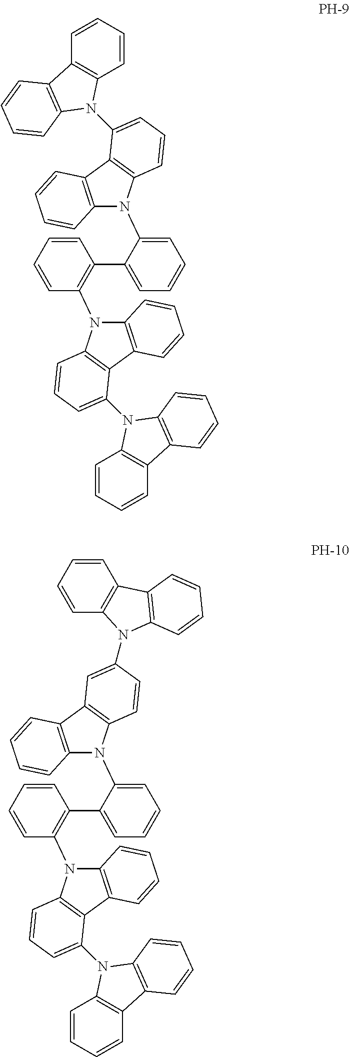 [SMILES: c1ccc(-n2c3ccccc3c3c(-n4c5ccccc5c5ccccc54)cccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1]

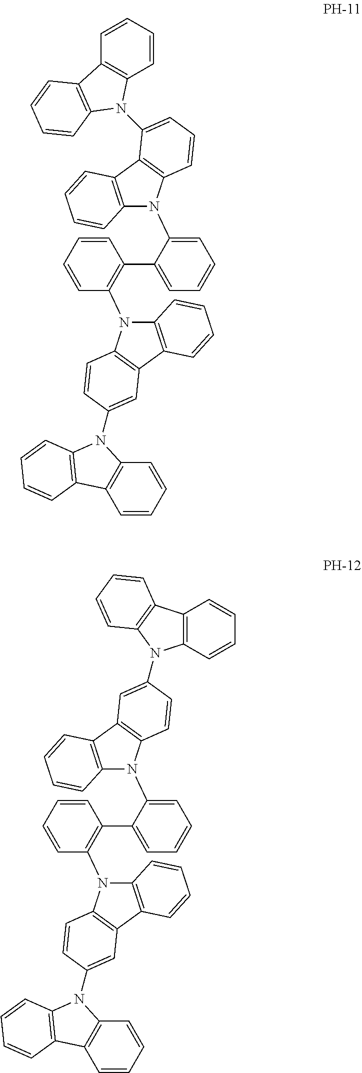 [SMILES: c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3cc(-n4c5ccccc5c5ccccc54)ccc32)c1]

Each of the first n-type host 254 in the first blue emitting layer 250 and the second n-type host 264 in the second blue emitting layer 260 is represented by Formula 3.

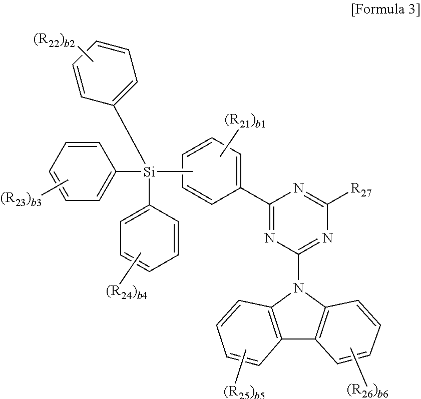

In Formula 3, each of b1, b5 and b6 is independently an integer of 0 to 4, each of b2 to b4 is independently an integer of 0 to 5, and

each of R₂₁ to R₂₇ is independently selected from the group consisting of deuterium, halogen, cyano, a substituted or unsubstituted C6 to C30 arylsilyl group, a substituted or unsubstituted C1 to C10 alkyl group, a substituted or unsubstituted C6 to C30 aryl group, a substituted or unsubstituted C3 to C60 heteroaryl group, a substituted or unsubstituted C6 to C60 arylamino group.

In an aspect of the present disclosure, R₂₇ may be selected from the group consisting of a substituted or unsubstituted C6 to C30 aryl group, e.g., phenyl or triphenylsilylphenyl, and a substituted or unsubstituted C3 to C60 heteroaryl group, e.g., carbazolyl.

In an aspect of the present disclosure, b5 may be 1, and R₂₅ may be a substituted or unsubstituted C3 to C60 heteroaryl group, e.g., carbazolyl.

For example, each of the first n-type host 254 and the second n-type host 264 may be independently selected from compounds in Formula 4. The first n-type host 254 and the second n-type host 264 may be same or different.

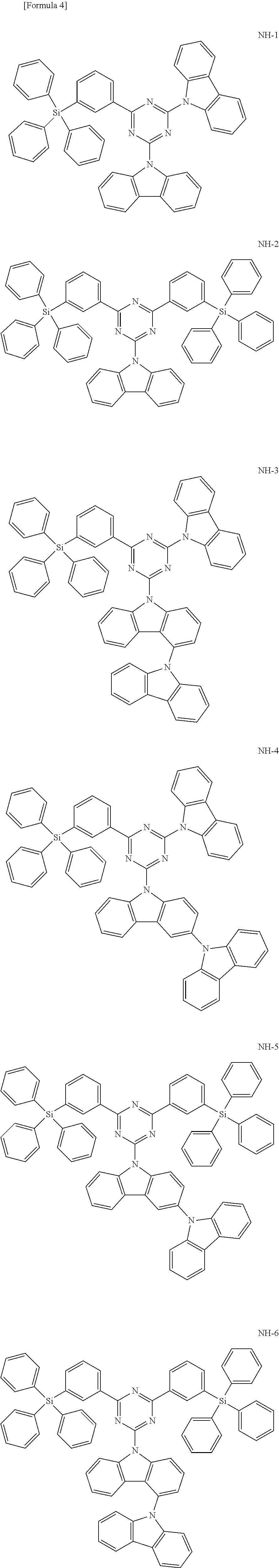

Each of the first phosphorescent compound 256 in the first blue emitting layer 250 and the second phosphorescent compound 266 in the second blue emitting layer 260 is represented by Formula 5.

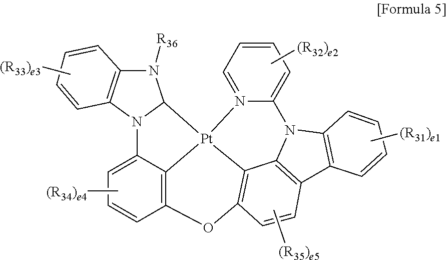

In Formula 5, each of e1, e2 and e3 is independently an integer of 0 to 4, e4 is an integer of 0 to 3, e5 is an integer of 0 to 2, and

each of R₃₁ to R₃₆ is independently selected from the group consisting of deuterium, halogen, cyano, a substituted or unsubstituted C1 to C20 alkyl group, a substituted or unsubstituted C3 to C20 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C60 heteroaryl group.

In an aspect of the present disclosure, each of R₃₁ to R₃₆ may be independently selected from the group consisting of a substituted or unsubstituted C1 to C20 alkyl group, e.g., methyl or tert-butyl, a substituted or unsubstituted C3 to C20 cycloalkyl group, e.g., adamantanyl, a substituted or unsubstituted C6 to C30 aryl group, e.g., phenyl or terphenyl, and a substituted or unsubstituted C3 to C60 heteroaryl group, e.g., carbazolyl.

In an aspect of the present disclosure, at least one of e1 to e5 may be a positive integer.

For example, each of the first phosphorescent compound 256 and the second phosphorescent compound 266 may be independently selected from compounds in Formula 6. The first phosphorescent compound 256 and the second phosphorescent compound 266 may be same or different.

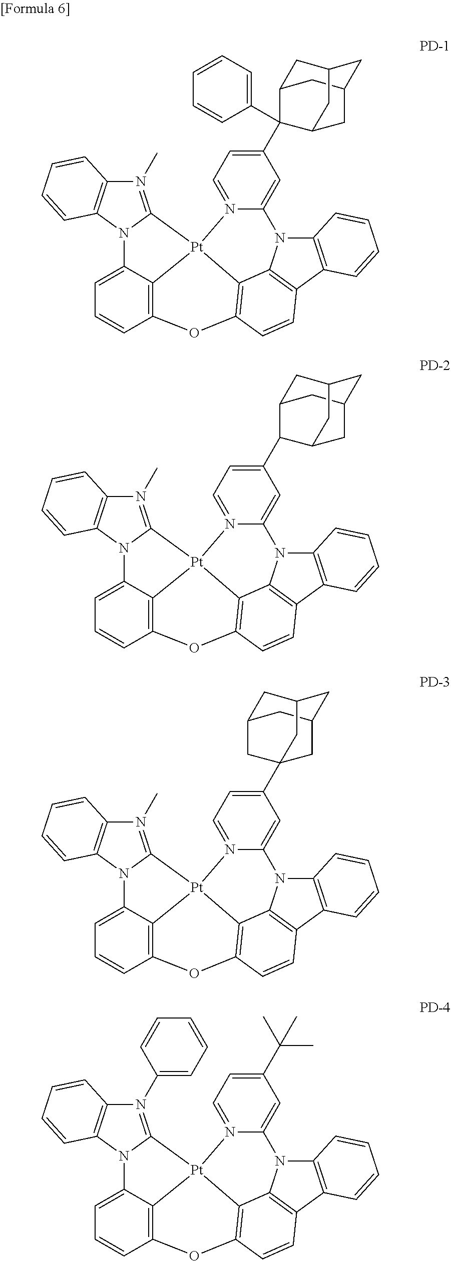

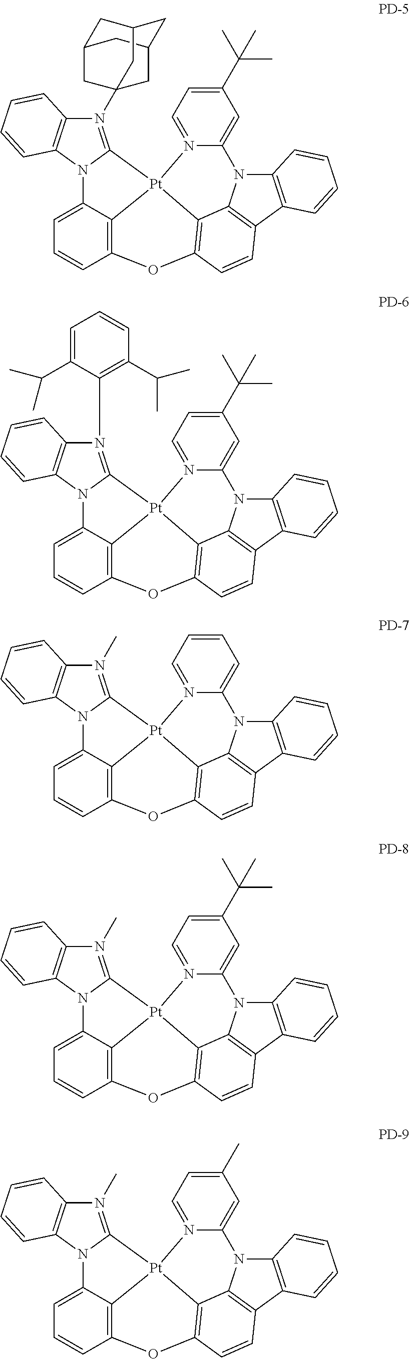

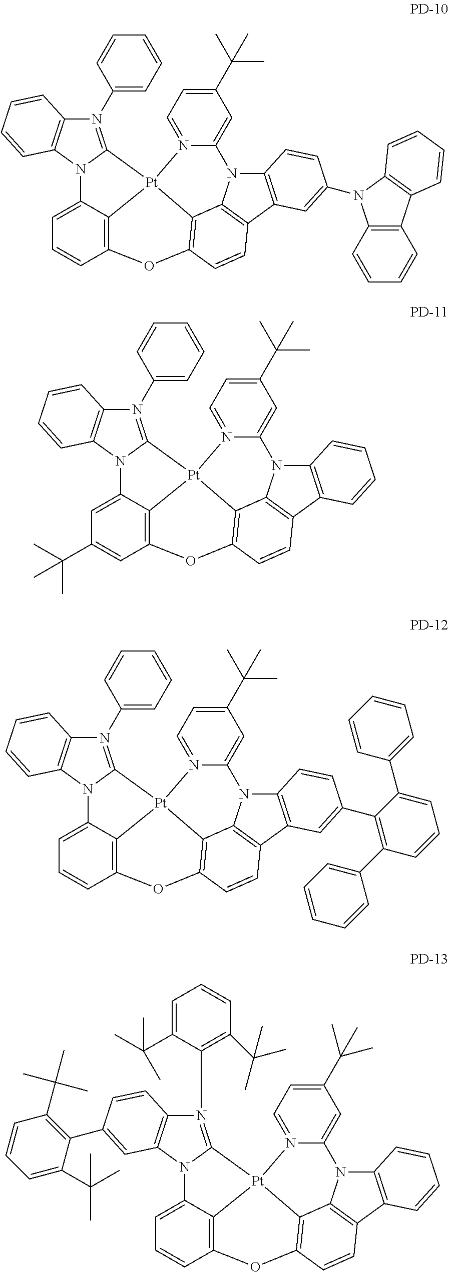

The fluorescent compound 268 in the second blue emitting layer 260 is represented by Formula 7.

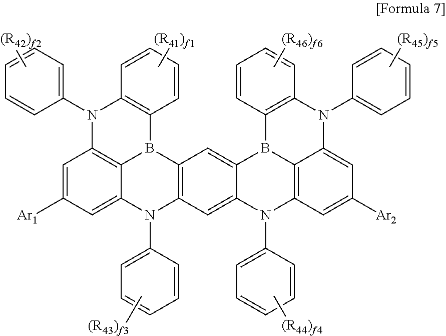

In Formula 7, each of f1 and f6 is independently an integer of 0 to 4, each of f2 to f5 is independently an integer of 0 to 5,
each of R₄₁ to R₄₆ is independently selected from the group consisting of deuterium, a substituted or unsubstituted C1 to C10 alkyl group, a substituted or unsubstituted C1 to C10 alkoxy group, a substituted or unsubstituted C6 to C30 arylsilyl group, a substituted or unsubstituted C6 to C30 arylamino group, a substituted or unsubstituted C6 to C30 aryl group and a substituted or unsubstituted C3 to C60 heteroaryl group, and
each of Ar₁ and Ar₂ is independently selected from the group consisting of a substituted or unsubstituted C6 to C30 arylamino group, a substituted or unsubstituted C6 to C30 aryl group and a substituted or unsubstituted C3 to C60 heteroaryl group.

In an aspect of the present disclosure, each of Ar₁ and Ar₂ may be a substituted or unsubstituted C6 to C30 arylamino group, e.g., diphenylamino, and a substituted or unsubstituted C3 to C60 heteroaryl group, e.g., carbazolyl.

In an aspect of the present disclosure, each of Ar₁ and Ar₂ may be a substituted or unsubstituted C6 to C30 arylamino group, e.g., diphenylamino.

In an aspect of the present disclosure, each of Ar₁ and Ar₂ may be a substituted or unsubstituted C3 to C60 heteroaryl group, e.g., carbazolyl.

For example, the fluorescent compound 268 may be one of compounds in Formula 8.

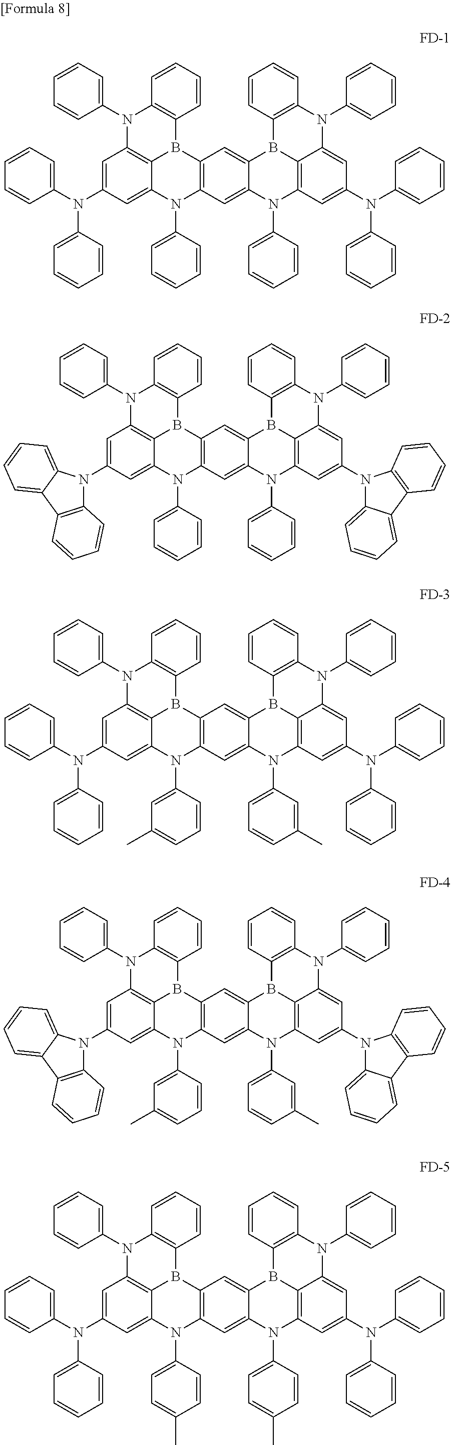

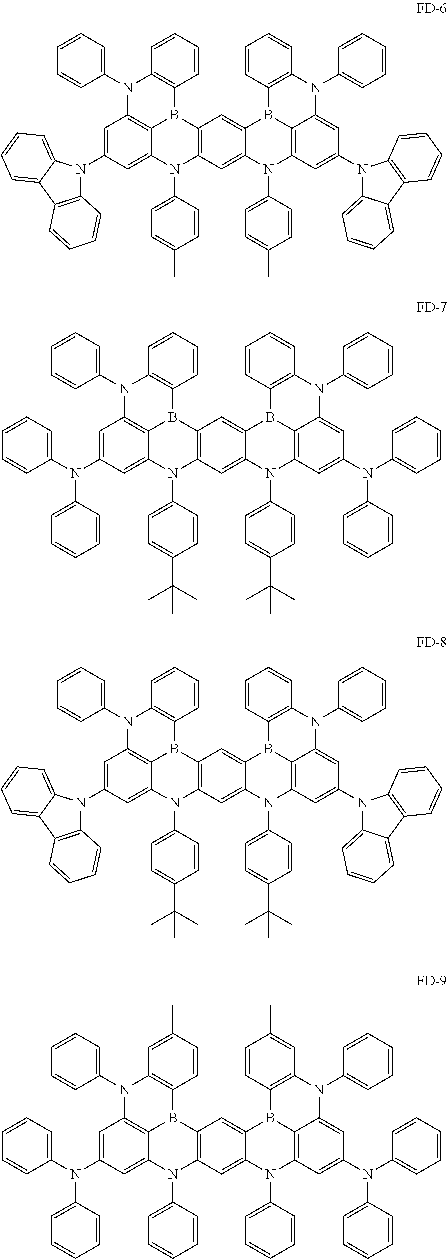

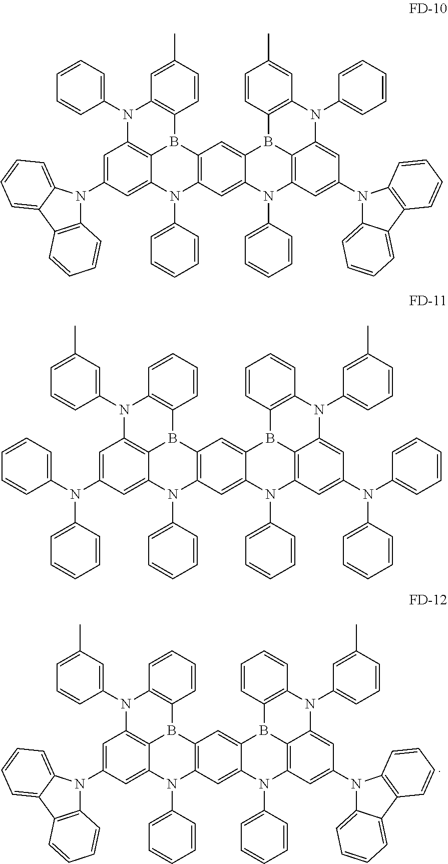 [SMILES: Cc1ccc2c(c1)N(c1ccccc1)c1cc(-n3c4ccccc4c4ccccc43)cc3c1B2c1cc2c(cc1N3c1ccccc1)N(c1ccccc1)c1cc(-n3c4ccccc4c4ccccc43)cc3c1B2c1ccc(C)cc1N3c1ccccc1 ; Cc1cccc(N2c3ccccc3B3c4cc5c(cc4N(c4ccccc4)c4cc(N(c6ccccc6)c6ccccc6)cc2c43)N(c2ccccc2)c2cc(N(c3ccccc3)c3ccccc3)cc3c2B5c2ccccc2N3c2cccc(C)c2)c1 ; Cc1cccc(N2c3ccccc3B3c4cc5c(cc4N(c4ccccc4)c4cc(-n6c7ccccc7c7ccccc76)cc2c43)N(c2ccccc2)c2cc(-n3c4ccccc4c4ccccc43)cc3c2B5c2ccccc2N3c2cccc(C)c2)c1]

In the first blue emitting layer 250, a maximum emission wavelength “λmax_{(PH1:NH1)}” of a mixture of the first p-type host 252 and the first n-type host 254 is shorter than 480 nm, and a maximum emission wavelength “λmax_{NH1}” of the first n-type host 254 is shorter than a maximum emission wavelength “λmax_{(PH1:NH1)}” of the mixture of the first p-type host 252 and the first n-type host 254 and longer than a maximum emission wavelength “λmax_{PH1}” of the first p-type host 252 (480 nm>λmax_{(PH1:NH1)}>λmaX_{NH1}>λmax_{PH1}).

In the first blue emitting layer 250, a difference between a lowest unoccupied molecular orbital (LUMO) energy level “LUMO_{PH1}” of the first p-type host 252 and a LUMO energy level “LUMO_{NH1}” of the first n-type host 254 is more than 0.3 eV, a difference between a highest occupied molecular orbital (HOMO) energy level “HOMO_{PH1}” of the first p-type host 252 and a HOMO energy level “HOMO_{NH1}” of the first n-type host 254 is more than 0.3 eV (LUMO_{PH1}−LUMO_{NH1}>0.3 eV, HOMO_{PH1}−HOMO_{NH1}>0.3 eV).

As a result, in the first blue emitting layer 250, an exciplex is generated between the first p-type host 252 and the first n-type host 254.

In the second blue emitting layer 260, a maximum emission wavelength “λmax_{(PH2:NH2)}” of a mixture of the second p-type host 262 and the second n-type host 264 is shorter than 480 nm, and a maximum emission wavelength “λmax_{NH2}” of the second n-type host 264 is shorter than a maximum emission wavelength “λmax_{(PH2:NH2)}” of the mixture of the second p-type host 262 and the second n-type host 264 and longer than a maximum emission wavelength “λmax_{PH2}” of the second p-type host 262 (480 nm>λmax_{(PH2:NH2)}>λmax_{NH2}>λmax_{PH2}).

In the second blue emitting layer 260, a difference between a LUMO energy level “LUMO_{PH2}” of the second p-type host 262 and a LUMO energy level “LUMO_{NH2}” of the second n-type host 264 is more than 0.3 eV, a difference between a HOMO energy level “HOMO_{PH2}” of the second p-type host 262 and a HOMO energy level “HOMO_{NH2}” of the second n-type host 264 is more than 0.3 eV (LUMO_{PH2}−LUMO_{NH2}>0.3 eV, HOMO_{PH2}−HOMO_{NH2}>0.3 eV).

As a result, in the second blue emitting layer 260, an exciplex is generated between the second p-type host 262 and the second n-type host 264.

Each of a maximum emission wavelength of the first phosphorescent compound 256 and a maximum emission wavelength of the second phosphorescent compound 266 is in a range of 450 to 470 nm. In addition, a difference between each of the maximum emission wavelength of the first phosphorescent compound 256 and the maximum emission wavelength of the second phosphorescent compound 266 and a maximum emission wavelength of the fluorescent compound 268 is 10 nm or less.

The fluorescent compound 268 has a Stokes Shift value being 10 nm or less. The Stokes Shift value is a difference between a maximum absorption wavelength and a maximum emission wavelength of the fluorescent compound. Since the fluorescent compound 268 has a Stokes Shift value being 10 nm or less, an energy transfer efficiency from the second phosphorescent compound 266 into the fluorescent compound 268 is improved.

A PL spectrum can be measured using an organic solvent, e.g., toluene, at room temperature, i.e., 25° C. For example, after a thin film having a thickness of 30 nm is formed using a solution, in which a compound dissolved in an organic solvent, e.g., toluene, with about 1*10⁻⁵M, a PL spectrum can be measured using a photoluminescence (PL) detection and a fluorescent spectrometer, e.g., FS-5 fluorescent spectrometer (Edinburgh Instruments).

Various methods of determining the HOMO energy level are known to the skilled person. For example, the HOMO energy level can be determined using a conventional surface analyser such as an AC3 surface analyser made by RKI instruments. The surface analyser may be used to interrogate a single film (neat film) of a compound with a thickness of 50 nm. The LUMO energy level can be calculated as follows:

LUMO=HOMO-bandgap.

The bandgap may be calculated using any conventional method known to the skilled person, such as from a UV-vis measurement of a single film with a thickness of 50 nm. For example, this can be done using a SCINCO S-3100 spectrophotometer. The HOMO and LUMO values of the compounds of the examples and embodiments disclosed herein may be determined in this way. Namely, the HOMO and LUMO values may be experimentally or empirically determined values of thin films, such as 50 nm films.

The blue EML 240 may have a thickness of 10 to 100 nm, and each of the first and second blue emitting layers 250 and 260 may have a thickness of 5 to 95 nm, preferably 5 to 50 nm. A thickness of the first blue emitting layer 250 and a thickness of the second blue emitting layer 260 may be same or different. In an aspect of the present disclosure, a thickness ratio of the second blue emitting layer 260 to the first blue emitting layer 250 may be in a range of 1:4 to 4:1, 1:3 to 3:1, 1:2.5 to 2.5:1, or 1:2 to 2:1, and preferably larger than 1:1 and no more than 4:1.

In an aspect of the present disclosure, the thickness of the first blue emitting layer 250 may be smaller than that of the second blue emitting layer 260. In this case, the emitting efficiency of the OLED D1 is further improved. For example, the first blue emitting layer 250 may have a thickness of 5 to 15 nm, and the second blue emitting layer 260 may have a thickness of 15 to 25 nm.

In the first blue emitting layer 250, a weight % of each of the first p-type host 252 and a weight % of the first n-type host 254 is greater than that of the first phosphorescent compound 256. The weight % of the first p-type host 252 and the weight % of the first n-type host 254 may be same or different. For example, in the first blue emitting layer 250, the first p-type host 252 and the first n-type host 254 may have the same weight %, and each of the first p-type host 252 and the first n-type host 254 may have a part by weight of 200 to 600 with respect to 100 parts by weight of the first phosphorescent compound 256.

For example, in the first blue emitting layer 250, a summation of a weight % of the first p-type host 252, a weight % of the first n-type host 254 and a weight % of the first phosphorescent compound 256 may be 100%. Namely, the first blue emitting layer 250 only includes the first p-type host 252, the first n-type host 254 and the first phosphorescent compound 256 without other material.

In the second blue emitting layer 260, a weight % of the second phosphorescent compound 266 is smaller than that of each of the second p-type host 262 and the second n-type host 264 and greater than that of the fluorescent compound 268. The weight % the second p-type host 262 and the weight % of the second n-type host 264 may be same or different. For example, in the second blue emitting layer 260, the second p-type host 262 and the second n-type host 264 may have the same weight %. With respect to 100 parts by weight of the fluorescent compound 268, each of the second p-type host 262 and the second n-type host 264 may have a part by weight of 5000 to 15000, and the second phosphorescent dopant 266 may have a part by weight of 1000 to 3000.

For example, in the second blue emitting layer 260, a summation of a weight % of the second p-type host 262, a weight % of the second n-type host 264, a weight % of the second phosphorescent compound 266 and a weight % of the fluorescent compound 268 may be 100%. Namely, the second blue emitting layer 260 only includes the second p-type host 262, the second n-type host 264, the second phosphorescent compound 266 and the fluorescent compound 268 without other material.

The light emitting layer 220 further include at least one of a hole transporting layer (HTL) 274 between the first electrode 210 and the EML 240 and an electron transporting layer (ETL) 282 between the second electrode 230 and the EML 240.

In addition, the light emitting layer 220 may further include at least one of a hole injection layer (HIL) 272 between the first electrode 210 and the HTL 274 and an electron injection layer (EIL) 284 between the second electrode 230 and the ETL 282.

Moreover, the light emitting layer 220 may further include at least one of an electron blocking layer (EBL) 276 between the HTL 274 and the EML 240 and a hole blocking layer (HBL) 286 between the EML 240 and the ETL 282.

For example, the OLED D1 may have a structure of the first electrode 210 as an anode, the HIL 272, the HTL 274, the EBL 276, the first blue emitting layer 250, the second blue emitting layer 260, the HBL 286, the ETL 282, the EIL 284 and the second electrode 230 as a cathode sequentially stacked. In this configuration, a first surface of the first blue emitting layer 250 contacts the second blue emitting layer 260, and a second surface of the first blue emitting layer 250 contacts the EBL 276. A first surface of the second blue emitting layer 260 contacts the first blue emitting layer 250, and a second surface of the second blue emitting layer 260 contacts the HBL 286.

For example, the HIL 272 may include a hole injection material selected from the group consisting of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine(CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile(dipyrazino[2,3-f:2′3′-h]quinoxaline-2,3,6,7,10,11-hexacarbonitrile (HAT-CN), 1,3,5-tris[4-(diphenylamino)phenyl]benzene (TDAPB), poly(3,4-ethylenedioxythiphene)polystyrene sulfonate (PEDOT/PSS), and N-(biphenyl-4-yl)-9,9-dimethyl-N-(4-(9-phenyl-9H-carbazol-3-yl)phenyl)-9H-fluoren-2-amine. Alternatively, the hole injection material of the HIL 272 may include a compound in Formula 9 as a host and a compound in Formula 10 as a dopant. In this case, the compound in Formula 10 may have a weight % of 1 to 10. For example, the HIL 272 may have a thickness of 1 to 30 nm.

The HTL 274 may include a hole transporting material selected from the group consisting of N,N′-diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), poly[N,N′-bis(4-butylpnehyl)-N,N′-bis(phenyl)-benzidine] (poly-TPD), (poly[(9,9-dioctylfluorenyl-2,7-diyl)-co-(4,4′-(N-(4-see-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, and N-(biphenyl-4-yl)-N-(4-(9-phenyl-9H-carbazol-3-yl)phenyl)biphenyl-4-amine. Alternatively, the hole transporting material of the HTL 274 may include the compound in Formula 9. For example, the HTL 274 may have a thickness of 5 to 150 nm. In a top-emission type OLED D1, the HTL 274 may have a thickness of 70 to 150 nm. In a bottom-emission type OLED D1, the HTL 274 may have a thickness of 5 to 50 nm.

The ETL 282 may include an electron transporting material selected from the group consisting of tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,08)-(1,1′-biphenyl-4-olato)aluminum (BAlq), 4,7-diphenyl-1,10-phenanthroline (Bphen), 2,9-bis(naphthalene-2-yl)4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline (TPQ), and diphenyl-4-triphenylsilyl-phenylphosphine oxide (TSPO1). Alternatively, the electron transporting material of the ETL 282 may include a compound in Formula 11. For example, the ETL 282 may have a thickness of 10 to 100 nm, preferably 20 to 40 nm.

The EIL 284 may include an electron injection material selected from an alkali halide compound, such as LiF, CsF, NaF, or BaF₂, and an organo-metallic compound, such as Liq, lithium benzoate, or sodium stearate. For example, the EIL 284 may have a thickness of 0.1 to 10 nm, preferably 0.5 to 2 nm.

The EBL 276 may include an electron blocking material selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene. Alternatively, the electron blocking material of the EBL 276 may be the same as the first p-type host 252 in the first blue emitting layer 250 or the second p-type host 262 in the second blue emitting layer 260. For example, the EBL 276 may have a thickness of 5 to 40 nm, preferably 10 to 20 nm.

The HBL 286 may include a hole blocking material selected from the group consisting of BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole, and TSPO1. Alternatively, the hole blocking material of the HBL 286 may be the same as the first n-type host 254 in the first blue emitting layer 250 or the second n-type host 264 in the second blue emitting layer 260. For example, the HBL 286 may have a thickness of 1 to 20 nm, preferably 1 to 10 nm.

The capping layer may include the above-mentioned hole transporting material and may have a thickness of 50 to 100 nm, preferably 70 to 80 nm.

In the OLED D1 of the present disclosure, the blue EML 240 includes the first blue emitting layer 250, which is disposed to be closer to the first electrode 210 as an anode, and the second blue emitting layer 260, which is disposed to be closer to the second electrode 230 as a cathode. The first blue emitting layer 250 includes the first phosphorescent compound 256 represented by Formula 5, and the second blue emitting layer 260 includes the second phosphorescent compound 266 represented by Formula 5 and the fluorescent compound 268 represented by Formula 7. As a result, the emitting efficiency and the color purity of the OLED D1 and the organic light emitting display device 100 are improved.

For example, when the blue EML includes a phosphorescent emitting layer without a PSF emitting layer, a recombination zone in the phosphorescent emitting layer is shifted toward the cathode so that a triplet-polaron quenching problem at an interface between the phosphorescent emitting layer and an adjacent layer, e.g., an HBL, to the phosphorescent emitting layer can occur. As a result, the emitting efficiency of the OLED is decreased.

However, as the OLED D1 of the present disclosure, when the second blue emitting layer 260, which is a PSF emitting layer, is disposed between the first blue emitting layer 250, which is a phosphorescent emitting layer, and the second electrode 230 as a cathode, a recombination zone is shifted toward a center of the blue EML 240 so that the above triplet-polaron quenching problem can be prevented. As a result, the emitting efficiency of the OLED D1 is improved.

In addition, when a thickness of the second blue emitting layer 260, which is a PSF emitting layer, is greater than that of the first blue emitting layer 250, which is a phosphorescent emitting layer, the emitting efficiency of the OLED D1 is further improved.

When the blue EML includes a phosphorescent emitting layer without a PSF emitting layer, the color purity of the OLED is degraded by high second emission peak of the phosphorescent compound.

However, as the OLED D1 of the present disclosure, when the second blue emitting layer 260, which is a PSF emitting layer, is disposed between the first blue emitting layer 250, which is a phosphorescent emitting layer, and the second electrode 230 as a cathode, the color purity of the OLED D1 is improved by narrow full width at half maximum (FWHM) of the second blue emitting layer 260.

### [OLED1]

An anode (ITO, 50 nm), an HIL (a compound in Formula 9 and a compound in Formula 10 (5 wt % doping), 10 nm), an HTL (the compound in Formula 9, 40 nm), an EBL (15 nm), a blue EML, an HBL (5 nm), an ETL (a compound in Formula 11, 30 nm), an EIL (LiF, 1 nm) and a cathode (Al, 100 nm) are sequentially deposited to form a bottom-emission type blue OLED.

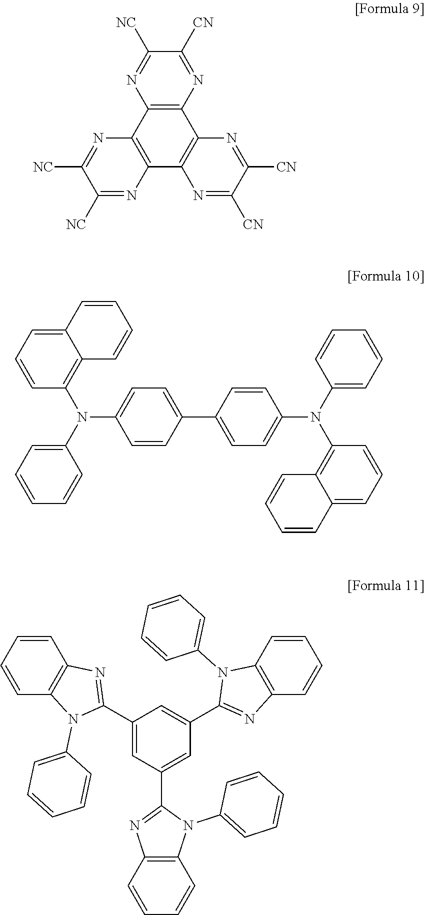 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; c1ccc(-n2c(-c3cc(-c4nc5ccccc5n4-c4ccccc4)cc(-c4nc5ccccc5n4-c4ccccc4)c3)nc3ccccc32)cc1]

### 1. COMPARATIVE EXAMPLES

### (1) Comparative Example 1 (Ref1)

The compound PH-1 in Formula 2 (44 wt %), the compound NH-1 in Formula 4 (44 wt %) and the compound PD-1 in Formula 6 (12 wt %) were used to form the blue EML (30 nm). The compound PH-1 in Formula 2 was used to form the EBL, and the compound NH-1 in Formula 4 was used to form the HBL.

### (2) Comparative Example 2 (Ref2)

The compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a first blue emitting layer (10 nm), and the compound PH-1 in Formula 2 (44 wt %), the compound NH-1 in Formula 4 (44 wt %) and the compound PD-1 in Formula 6 (12 wt %) were used to form a second blue emitting layer (20 nm) on the first blue emitting layer.

The compound PH-1 in Formula 2 was used to form the EBL, and the compound NH-1 in Formula 4 was used to form the HBL.

### (3) Comparative Example 3 (Ref3)

The compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a first blue emitting layer (15 nm), and the compound PH-1 in Formula 2 (44 wt %), the compound NH-1 in Formula 4 (44 wt %) and the compound PD-1 in Formula 6 (12 wt %) were used to form a second blue emitting layer (15 nm) on the first blue emitting layer.

The compound PH-1 in Formula 2 was used to form the EBL, and the compound NH-1 in Formula 4 was used to form the HBL.

### (4) Comparative Example 4 (Ref4)

The compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a first blue emitting layer (20 nm), and the compound PH-1 in Formula 2 (44 wt %), the compound NH-1 in Formula 4 (44 wt %) and the compound PD-1 in Formula 6 (12 wt %) were used to form a second blue emitting layer (10 nm) on the first blue emitting layer.

The compound PH-1 in Formula 2 was used to form the EBL, and the compound NH-1 in Formula 4 was used to form the HBL.

### 2. EXAMPLES

### (1) Example 1 (Ex1)

The compound PH-1 in Formula 2 (44 wt %), the compound NH-1 in Formula 4 (44 wt %) and the compound PD-1 in Formula 6 (12 wt %) were used to form a first blue emitting layer (10 nm), and the compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a second blue emitting layer (20 nm) on the first blue emitting layer.

The compound PH-1 in Formula 2 was used to form the EBL, and the compound NH-1 in Formula 4 was used to form the HBL.

### (2) Example 2 (Ex2)

The compound PH-1 in Formula 2 (44 wt %), the compound NH-1 in Formula 4 (44 wt %) and the compound PD-1 in Formula 6 (12 wt %) were used to form a first blue emitting layer (15 nm), and the compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a second blue emitting layer (15 nm) on the first blue emitting layer.

The compound PH-1 in Formula 2 was used to form the EBL, and the compound NH-1 in Formula 4 was used to form the HBL.

### (3) Example 3 (Ex3)

The compound PH-1 in Formula 2 (44 wt %), the compound NH-1 in Formula 4 (44 wt %) and the compound PD-1 in Formula 6 (12 wt %) were used to form a first blue emitting layer (20 nm), and the compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a second blue emitting layer (10 nm) on the first blue emitting layer.

The compound PH-1 in Formula 2 was used to form the EBL, and the compound NH-1 in Formula 4 was used to form the HBL.

The emitting properties, i.e., a driving voltage (V, %), an external quantum efficiency (EQE, %), a color coordinate index (CIEx, CIEy) and a maximum emission wavelength (λ_{MAX}, nm), of the OLED in Comparative Examples 1 to 4 and Examples 1 to 3 are measured and listed in Table 1. The driving voltage is a relative value to Comparative Example 1.

TABLE 1

| | EML | | V | EQE | CIEx | CIEy | λ_{MAX} |
|---|---|---|---|---|---|---|---|
| Ref1 | PH-1:NH-1:PD-1 (30 nm) | | 100 | 21 | 0.135 | 0.150 | 462 |
| Ref2 | PH-1:NH-1:PD-1:FD-1 | PH-1:NH-1:PD-1 | 100 | 22 | 0.130 | 0.131 | 468 |
| | (10 nm) | (20 nm) | | | | | |
| Ref3 | PH-1:NH-1:PD-1:FD-1 | PH-1:NH-1:PD-1 | 100 | 22 | 0.128 | 0.130 | 470 |
| | (15 nm) | (15 nm) | | | | | |
| Ref4 | PH-1:NH-1:PD-1:FD-1 | PH-1:NH-1:PD-1 | 100 | 23 | 0.131 | 0.131 | 470 |
| | (20 nm) | (10 nm) | | | | | |
| Ex1 | PH-1:NH-1:PD-1 | PH-1:NH-1:PD-1:FD-1 | 100 | 27 | 0.131 | 0.131 | 470 |
| | (10 nm) | (20 nm) | | | | | |
| Ex2 | PH-1:NH-1:PD-1 | PH-1:NH-1:PD-1:FD-1 | 100 | 26 | 0.128 | 0.130 | 470 |
| | (15 nm) | (15 nm) | | | | | |
| Ex3 | PH-1:NH-1:PD-1 | PH-1:NH-1:PD-1:FD-1 | 100 | 25 | 0.130 | 0.131 | 468 |
| | (20 nm) | (10 nm) | | | | | |

As shown in Table 1, in comparison to the OLED of Comparative Examples 1 to 4, the OLED of Examples 1 to 3 has an advantage in at least one of the emitting efficiency and the color purity.

For example, in comparison to Comparative Example 1, the emitting efficiency and the color purity of the OLED of Examples 1 to 3, in which a PSF emitting layer is disposed between a phosphorescent emitting layer and a second electrode as a cathode, e.g., between the phosphorescent emitting layer and an HBL, are improved.

In addition, in comparison to Examples 2 and 3, the emitting efficiency of the OLED of Example 1, in which a thickness of the PSF emitting layer is greater than that of the phosphorescent emitting layer, is further improved.

On the other hand, in comparison to Examples 1 to 3, when a PSF emitting layer is disposed between a phosphorescent emitting layer and a first electrode as an anode, e.g., between the phosphorescent emitting layer and an EBL as Comparative Examples 2 to 4, the emitting efficiency of the OLED is decreased.

### [OLED2]

An anode (ITO(5 nm)/Ag(100 nm)/ITO(5 nm)), an HIL (the compound in Formula 9 and the compound in Formula 10 (5 wt % doping), 10 nm), an HTL (the compound in Formula 9, 110 nm), an EBL (15 nm), a blue EML, an HBL (5 nm), an ETL (the compound in Formula 11, 30 nm), an EIL (LiF, 1 nm), a cathode (Mg:Ag(1:9), 12 nm) and a capping layer (the compound in Formula 9, 75 nm) are sequentially deposited to form a top-emission type blue OLED.

### 3. COMPARATIVE EXAMPLE 5 (REF5)

The compound PH-1 in Formula 2 (44 wt %), the compound NH-1 in Formula 4 (44 wt %) and the compound PD-1 in Formula 6 (12 wt %) were used to form the blue EML (30 nm). The compound PH-1 in Formula 2 was used to form the EBL, and the compound NH-1 in Formula 4 was used to form the HBL.

### 4. EXAMPLES

### (1) Example 4 (Ex4)

The compound PH-1 in Formula 2 (44 wt %), the compound NH-1 in Formula 4 (44 wt %) and the compound PD-1 in Formula 6 (12 wt %) were used to form a first blue emitting layer (10 nm), and the compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a second blue emitting layer (20 nm) on the first blue emitting layer.

The compound PH-1 in Formula 2 was used to form the EBL, and the compound NH-1 in Formula 4 was used to form the HBL.

### (5) Example 5 (Ex5)

The compound PH-1 in Formula 2 (44 wt %), the compound NH-1 in Formula 4 (44 wt %) and the compound PD-1 in Formula 6 (12 wt %) were used to form a first blue emitting layer (15 nm), and the compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a second blue emitting layer (15 nm) on the first blue emitting layer.

The compound PH-1 in Formula 2 was used to form the EBL, and the compound NH-1 in Formula 4 was used to form the HBL.

### (6) Example 6 (Ex6)

The compound PH-1 in Formula 2 (44 wt %), the compound NH-1 in Formula 4 (44 wt %) and the compound PD-1 in Formula 6 (12 wt %) were used to form a first blue emitting layer (20 nm), and the compound PH-1 in Formula 2 (44 wt %), the compound NH-1 in Formula 4 (44 wt %), the compound PD-1 in Formula 6 (11.5 wt %) and the compound FD-1 in Formula 8 (0.5 wt %) were used to form a second blue emitting layer (10 nm) on the first blue emitting layer.

The compound PH-1 in Formula 2 was used to form the EBL, and the compound NH-1 in Formula 4 was used to form the HBL.

The emitting properties, i.e., a driving voltage (V, %), a brightness (cd/A), a color coordinate index (CIEy) and a maximum emission wavelength (λ_{MAX}, nm), of the OLED in Comparative Example 5 and Examples 4 to 6 are measured and listed in Table 2. The driving voltage is a relative value to Comparative Example 4.

TABLE 2

| | EML | | V | cd/A | CIEy | λ_{MAX} |
|---|---|---|---|---|---|---|
| Ref5 | PH-1:NH-1:PD-1 (30 nm) | | 100 | 15.4 | 0.061 | 463 |
| Ex4 | PH-1:NH-1:PD-1 | PH-1:NH-1:PD-1:FD-1 | 100 | 25.7 | 0.063 | 465 |
| | (10 nm) | (20 nm) | | | | |
| Ex5 | PH-1:NH-1:PD-1 | PH-1:NH-1:PD-1:FD-1 | 100 | 23.9 | 0.063 | 465 |
| | (15 nm) | (15 nm) | | | | |
| Ex6 | PH-1:NH-1:PD-1 | PH-1:NH-1:PD-1:FD-1 | 100 | 21.8 | 0.062 | 464 |
| | (20 nm) | (10 nm) | | | | |

As shown in Table 2, in comparison to the OLED of Comparative Example 5, the emitting efficiency, i.e., brightness, of the OLED of Examples 4 to 6 is significantly increased.

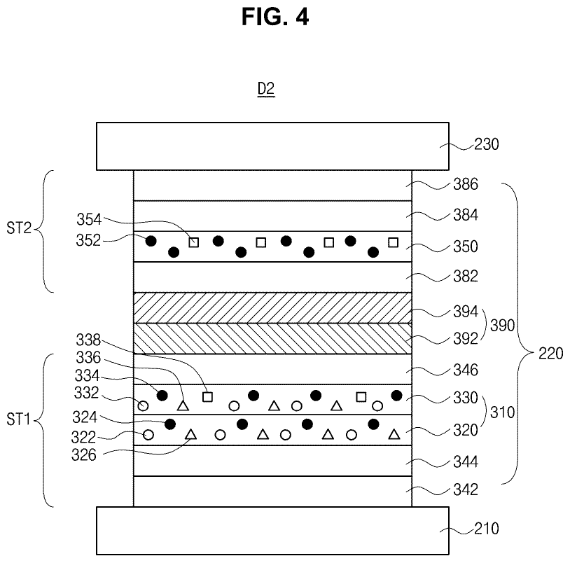

FIG. 4 is a schematic cross-sectional view of an OLED according to a third embodiment of the present disclosure.

As illustrated in FIG. 4, the OLED D2 includes first and second electrodes 210 and 230 facing each other and an organic light emitting layer 220 therebetween. The organic light emitting layer 220 includes a first emitting part ST1 including a first blue EML 310 and a second emitting part ST2 including a second blue EML 350. The organic light emitting layer 220 may include a CGL 390 between the first and second emitting parts ST1 and ST2. The OLED D2 in a top-emission type may further include a capping layer on the second electrode 230 to enhance a light extraction efficiency.

The organic light emitting display device 100 may include a red pixel region, a green pixel region and a blue pixel region, and the OLED D2 may be positioned in the blue pixel region.

The first electrode 210 is an anode, and the second electrode 230 is a cathode. One of the first and second electrodes 210 and 230 may be a reflective electrode, and the other one of the first and second electrodes 210 and 230 may be a transparent (or a semi-transparent) electrode.

In a top-emission type OLED D2, the first electrode 210 may be a reflective electrode and may have a structure of ITO/Ag/ITO, and the second electrode 230 may be a transparent electrode and may be formed of Mg:Ag with a weight % ratio of 1:9.

In a bottom-emission type OLED D2, the first electrode 210 may be a transparent electrode and may be formed of ITO, and the second electrode 230 may be a reflective electrode and may be formed of Al.

The first blue EML 310 includes a first blue emitting layer 320, which is closer to the first electrode 210 as an anode, and a second blue emitting layer 330, which is closer to the second electrode 230 as a cathode. The second blue emitting layer 330 contacts and is disposed on the first blue emitting layer 320 so that the first blue EML 310 has a double-layered structure.

The first blue emitting layer 320 includes a first phosphorescent compound 326. In addition, the first blue emitting layer 320 may further include a first p-type host 322 and a first n-type host 324. The first blue emitting layer 320 is a phosphorescent emitting layer.

The first phosphorescent compound 326 serves as an emitter (e.g., dopant) so that the blue light is provided (emitted) from the first phosphorescent compound 326. An exciplex can be generated by the first p-type host 322 and the first n-type host 324.

The second blue emitting layer 330 includes a second phosphorescent compound 336 and a fluorescent compound 338. In addition, the second blue emitting layer 330 may further include a second p-type host 332 and a second n-type host 334. The second blue emitting layer 330 is a phosphor-sensitized fluorescence (PSF) emitting layer.

The fluorescent compound 338 serves as an emitter (e.g., dopant) so that the blue light is provided (emitted) from the fluorescent compound 338. An energy may be transferred into the fluorescent compound 338 by the second phosphorescent compound 336. The second phosphorescent compound 336 may be referred to as an auxiliary dopant or auxiliary host. An exciplex can be generated by the second p-type host 332 and the second n-type host 334.

Each of the first p-type host 322 in the first blue emitting layer 320 and the second p-type host 332 in the second blue emitting layer 330 is a compound represented by Formula 1. For example, each of the first p-type host 322 in the first blue emitting layer 320 and the second p-type host 332 in the second blue emitting layer 330 may be independently selected from the compounds in Formula 2.

Each of the first n-type host 324 in the first blue emitting layer 320 and the second n-type host 334 in the second blue emitting layer 330 is a compound represented by Formula 3. For example, each of the first n-type host 324 in the first blue emitting layer 320 and the second n-type host 334 in the second blue emitting layer 330 may be independently selected from the compounds in Formula 4.

Each of the first phosphorescent compound 326 in the first blue emitting layer 320 and the second phosphorescent compound 336 in the second blue emitting layer 330 is a compound represented by Formula 5. For example, each of the first phosphorescent compound 326 in the first blue emitting layer 320 and the second phosphorescent compound 336 in the second blue emitting layer 330 may be independently selected from the compounds in Formula 6.

The fluorescent compound 338 is a compound represented by Formula 7. For example, the fluorescent compound 338 may be one of the compounds in Formula 8.

The first blue EML 310 may have a thickness of 10 to 100 nm, and each of the first and second blue emitting layers 320 and 330 may have a thickness of 5 to 95 nm, preferably 5 to 50 nm. A thickness of the first blue emitting layer 320 and a thickness of the second blue emitting layer 330 may be same or different.

In an aspect of the present disclosure, the thickness of the first blue emitting layer 320 may be smaller than that of the second blue emitting layer 330. In this case, the emitting efficiency of the OLED D2 is further improved. For example, the first blue emitting layer 320 may have a thickness of 5 to 15 nm, and the second blue emitting layer 330 may have a thickness of 15 to 25 nm.

In the first blue emitting layer 320, a weight % of each of the first p-type host 322 and a weight % of the first n-type host 324 is greater than that of the first phosphorescent compound 326. The weight % of the first p-type host 322 and the weight % of the first n-type host 324 may be same or different. For example, in the first blue emitting layer 320, the first p-type host 322 and the first n-type host 324 may have the same weight %, and each of the first p-type host 322 and the first n-type host 324 may have a part by weight of 200 to 600 with respect to 100 parts by weight of the first phosphorescent compound 326.

For example, in the first blue emitting layer 320, a summation of a weight % of the first p-type host 322, a weight % of the first n-type host 324 and a weight % of the first phosphorescent compound 326 may be 100%.

In the second blue emitting layer 330, a weight % of the second phosphorescent compound 336 is smaller than that of each of the second p-type host 332 and the second n-type host 334 and greater than that of the fluorescent compound 338. The weight % the second p-type host 332 and the weight % of the second n-type host 334 may be same or different. For example, in the second blue emitting layer 330, the second p-type host 332 and the second n-type host 334 may have the same weight %. With respect to 100 parts by weight of the fluorescent compound 338, each of the second p-type host 332 and the second n-type host 334 may have a part by weight of 5000 to 15000, and the second phosphorescent dopant 336 may have a part by weight of 1000 to 3000.

For example, in the second blue emitting layer 330, a summation of a weight % of the second p-type host 332, a weight % of the second n-type host 334, a weight % of the second phosphorescent compound 336 and a weight % of the fluorescent compound 338 may be 100%.

The first emitting part ST1 may further include at least one of a first HTL 344 under the first blue EML 310 and a first ETL 346 over the first blue EML 310.

In addition, the first emitting part ST1 may further include an HIL 342 between the first electrode 210 and the first HTL 344.

Moreover, the first emitting part ST1 may further include at least one of a first EBL between the first HTL 344 and the first blue EML 310 and a first HBL between the first blue EML 310 and the first ETL 346.

The second blue EML 350 may have a single-layered structure. The second blue EML 350 may have a thickness of 10 to 100 nm.

The second blue EML 350 may include a blue host 352 and a blue dopant (e.g., an emitter) 354. The second blue EML 350 may further include an auxiliary dopant (or an auxiliary host). In the second blue EML 350, a weight % of the blue dopant 354 may be smaller than that of each of the blue host 352 and the auxiliary dopant.

For example, the blue host 352 may be selected from the group consisting of mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spiorobifluoren-2-yl-diphenyl-phosphine oxide (SPPO1), and 9,9′-(5-(triphenylsilyl)-1,3-phenylene)bis(9H-carbazole) (SimCP).

For example, the blue dopant 354 may be selected from the group consisting of perylene, 4,4′-bis[4-(di-p-tolylamino)styryl]biphenyl (DPAVBi), 4-(di-p-tolylamino)-4,4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spiorfluorene (spiro-DPVBi), [1,4-bis[2-[4-[N,N-di(p-tolyl)amino]phenyl]vinyl] benzene (DSB), 1,4-di-[4-(N,N-diphenyl)amino]styryl-benzene (DSA), 2,5,8,11-tetra-tetr-butylperylene (TBPe), bis(2-hydroxylphenyl)-pyridine)beryllium (Bepp2) and 9-(9-Phenylcarbazole-3-yl)-10-(naphthalene-1-yl)anthracene (PCAN).

In an aspect of the present disclosure, the blue host 352 may include at least one of compounds in Formula 12.

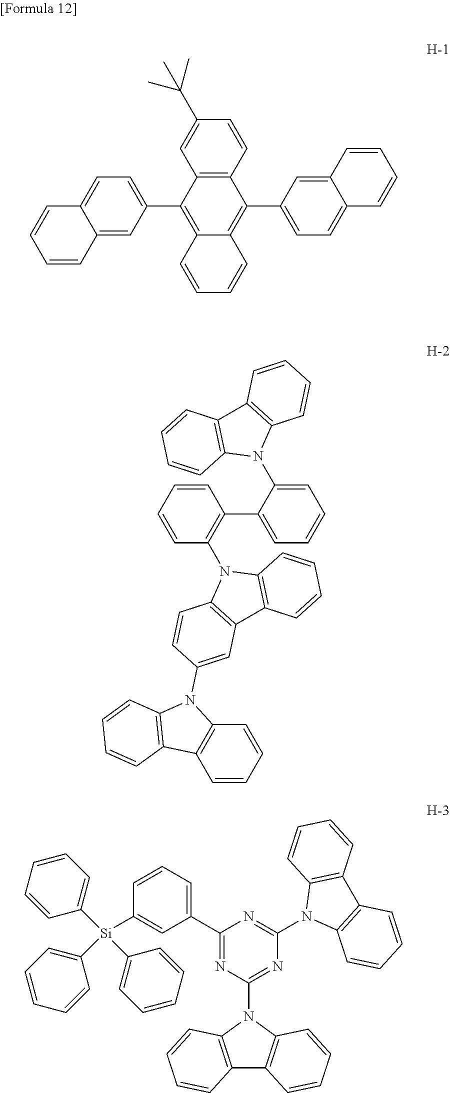

In an aspect of the present disclosure, the blue dopant 354 may be a fluorescent compound being selected from compounds in Formula 13.

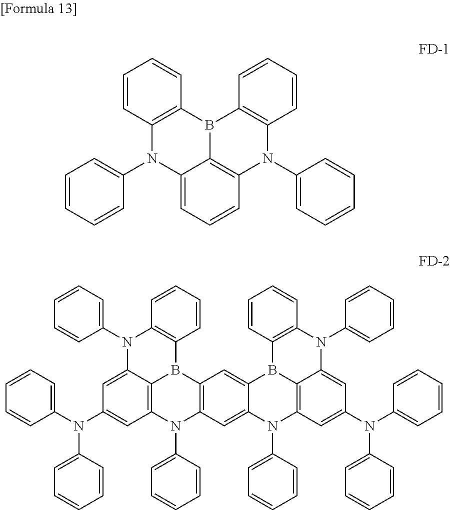 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

In an aspect of the present disclosure, the auxiliary dopant may be a phosphorescent compound or a delayed fluorescent compound. For example, the auxiliary dopant may be selected from compounds in Formula 14.

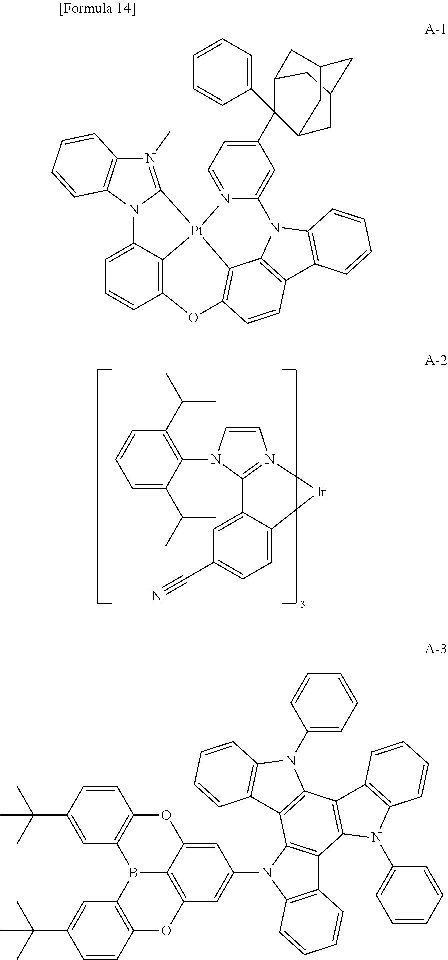

In an aspect of the present disclosure, the second blue EML 350 may be a fluorescent emitting layer including the compound H-1 in Formula 12 and the compound FD-1 in Formula 13.

In an aspect of the present disclosure, the second blue EML 350 may be a PSF emitting layer including the compound H-2 in Formula 12, the compound H-3 in Formula 12, the compound FD-2 in Formula 13 and the compound A-1 or A-2 in Formula 14.

In an aspect of the present disclosure, the second blue EML 350 may be a hyper-fluorescence emitting layer including the compound H-2 in Formula 12, the compound H-3 in Formula 12, the compound FD-2 in Formula 13 and the compound A-3 in Formula 14.

The second emitting part ST2 may further include at least one of a second HTL 382 under the second blue EML 350 and a second ETL 384 over the second blue EML 350.

In addition, the second emitting part ST2 may further include an EIL 386 between the second electrode 230 and the second ETL 384.

Moreover, the second emitting part ST2 may further include at least one of a second EBL between the second HTL 382 and the second blue EML 350 and a second HBL between the second blue EML 350 and the second ETL 384.

For example, the HIL 342 may include the above-mentioned hole injection material and may have a thickness of 1 to 30 nm, preferably 5 to 15 nm.

Each of the first and second HTLs 344 and 382 may include the above-mentioned hole transporting material and may have a thickness of 5 to 15 nm.

Each of the first and second ETLs 346 and 384 may include the above-mentioned electron transporting material and may have a thickness of 10 to 100 nm, preferably 20 to 40 nm.

The EIL 386 may include the above-mentioned electron injection material and may have a thickness of 0.1 to 10 nm, preferably 0.5 to 2 nm.

Each of the first and second EBLs may include the above-mentioned electron blocking material and may have a thickness of 5 to 40 nm, preferably 10 to 20 nm.

Each of the first and second HBLs may include the above-mentioned hole blocking material and may have a thickness of 1 to 20 nm, preferably 1 to 10 nm.

The CGL 390 is positioned between the first and second emitting parts ST1 and ST2. Namely, the first and second emitting parts ST1 and ST2 is connected to each other through the CGL 390. The CGL 390 may be a PN-junction CGL of an N-type CGL 392 and a P-type CGL 394.

The N-type CGL 392 is positioned between the first ETL 346 and the second HTL 382, and the P-type CGL 394 is positioned between the N-type CGL 392 and the second HTL 382.

The N-type CGL 392 provides an electron into the first blue EML 310 of the first emitting part ST1, and the P-type CGL 394 provides a hole into the second blue EML 350 of the second emitting part ST2.

The N-type CGL 392 may be an organic layer doped with an alkali metal, e.g., Li, Na, K and Cs, and/or an alkali earth metal, e.g., Mg, Sr, Ba and Ra. For example, the N-type CGL 392 may be formed of an N-type charge generation material including a host being the organic material, e.g., 4,7-dipheny-1,10-phenanthroline (Bphen) and MTDATA, a dopant being an alkali metal and/or an alkali earth metal, and the dopant may be doped with a weight % of 0.01 to 30.

The P-type CGL 394 may be formed of a P-type charge generation material including an inorganic material, e.g., tungsten oxide (WOx), molybdenum oxide (MoOx), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The capping layer may include the above-mentioned hole transporting material and may have a thickness of 50 to 100, preferably 70 to 80 nm.

In the blue pixel region, the organic light emitting layer 220 of the OLED D2 includes the first blue EML 310 and the second blue EML 350 to have a tandem structure.

The first blue EML 310 includes the first blue emitting layer 320, which includes the first p-type host 322, the first n-type host 324 and the first phosphorescent compound 326, and the second blue emitting layer 330, which includes the second p-type host 332, the second n-type host 334, the second phosphorescent compound 336 and the fluorescent compound 338. Each of the first and second p-type hosts 322 and 332 is a compound represented by Formula 1, and each of the first and second n-type hosts 324 and 334 is a compound represented by Formula 3. Each of the first and second phosphorescent compounds 326 and 336 is represented by Formula 5, and the fluorescent compound 338 is represented by Formula 7.

Accordingly, the OLED D2 and the organic light emitting display device 100 of the present disclosure have advantages in the emitting efficiency and the color purity.

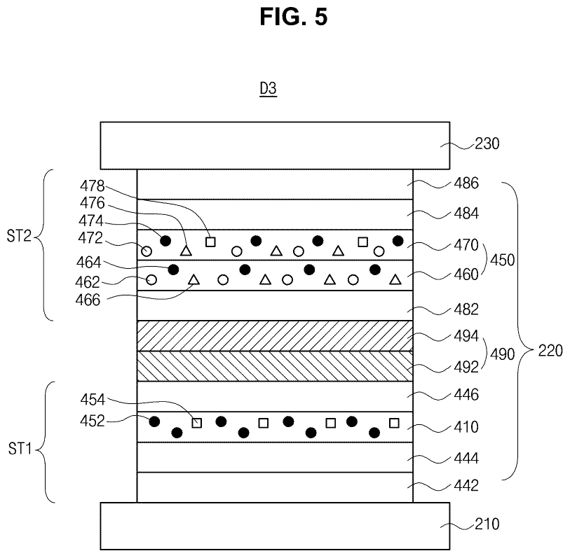

FIG. 5 is a schematic cross-sectional view of an OLED according to a fourth embodiment of the present disclosure.

As illustrated in FIG. 5, the OLED D3 includes first and second electrodes 210 and 230 facing each other and an organic light emitting layer 220 therebetween. The organic light emitting layer 220 includes a first emitting part ST1 including a first blue EML 410 and a second emitting part ST2 including a second blue EML 450. The organic light emitting layer 220 may include a CGL 490 between the first and second emitting parts ST1 and ST2. The top-emission type OLED D3 may further include a capping layer on the second electrode 230 to enhance a light extraction efficiency.

The organic light emitting display device 100 (of FIG. 2) may include a red pixel region, a green pixel region and a blue pixel region, and the OLED D3 may be positioned in the blue pixel region.

The first electrode 210 is an anode, and the second electrode 230 is a cathode. One of the first and second electrodes 210 and 230 may be a reflective electrode, and the other one of the first and second electrodes 210 and 230 may be a transparent (or a semi-transparent) electrode.

In a top-emission type OLED D3, the first electrode 210 may be a reflective electrode and may have a structure of ITO/Ag/ITO, and the second electrode 230 may be a transparent electrode and may be formed of Mg:Ag with a weight % ratio of 1:9.

In a bottom-emission type OLED D3, the first electrode 210 may be a transparent electrode and may be formed of ITO, and the second electrode 230 may be a reflective electrode and may be formed of Al.

The first emitting part ST1 may further include at least one of a first HTL 444 under the first blue EML 410 and a first ETL 446 over the first blue EML 410.

In addition, the first emitting part ST1 may further include an HIL 442 between the first electrode 210 and the first HTL 444.

Moreover, the first emitting part ST1 may further include at least one of a first EBL between the first HTL 444 and the first blue EML 410 and a first HBL between the first blue EML 410 and the first ETL 446.

The second emitting part ST2 may further include at least one of a second HTL 482 under the second blue EML 450 and a second ETL 484 over the second blue EML 450.

In addition, the second emitting part ST2 may further include an EIL 486 between the second electrode 230 and the second ETL 484.

Moreover, the second emitting part ST2 may further include at least one of a second EBL between the second HTL 482 and the second blue EML 450 and a second HBL between the second blue EML 450 and the second ETL 484.

For example, the HIL 442 may include the above-mentioned hole injection material and may have a thickness of 1 to 30 nm, preferably 5 to 15 nm.

Each of the first and second HTLs 444 and 482 may include the above-mentioned hole transporting material and may have a thickness of 5 to 150 nm.

Each of the first and second ETLs 446 and 484 may include the above-mentioned electron transporting material and may have a thickness of 10 to 100 nm, preferably 20 to 40 nm.

The EIL 486 may include the above-mentioned electron injection material and may have a thickness of 0.1 to 10 nm, preferably 0.5 to 2 nm.

Each of the first and second EBLs may include the above-mentioned electron blocking material and may have a thickness of 5 to 40 nm, preferably 10 to 20 nm.

Each of the first and second HBLs may include the above-mentioned hole blocking material and may have a thickness of 1 to 20 nm, preferably 1 to 10 nm.

The CGL 490 is positioned between the first and second emitting parts ST1 and ST2. Namely, the first and second emitting parts ST1 and ST2 is connected to each other through the CGL 490. The CGL 490 may be a PN-junction CGL of an N-type CGL 492 and a P-type CGL 494.

The N-type CGL 492 is positioned between the first ETL 446 and the second HTL 482, and the P-type CGL 494 is positioned between the N-type CGL 492 and the second HTL 482.

The N-type CGL 492 provides an electron into the first blue EML 410 of the first emitting part ST1, and the P-type CGL 494 provides a hole into the second blue EML 450 of the second emitting part ST2.

The N-type CGL 492 may include the above-mentioned N-type charge generation material, and the P-type CGL 494 may include the above-mentioned P-type charge generation material.

The capping layer may include the above-mentioned hole transporting material and may have a thickness of 50 to 100 nm, preferably 70 to 80 nm.

The first blue EML 410 may have a single-layered structure. The first blue EML 410 may have a thickness of 10 to 100 nm.

The first blue EML 410 may include a blue host 452 and a blue dopant (e.g., an emitter) 454. The first blue EML 410 may further include an auxiliary dopant (or an auxiliary host). In the first blue EML 410, a weight % of the blue dopant 454 may be smaller than that of each of the blue host 452 and the auxiliary dopant.

For example, the blue host 452 may be include at least one of the compounds in Formula 12, the blue dopant 454 may be selected from the compounds in Formula 13, and the auxiliary dopant may be selected from the compounds in Formula 14.

The first blue EML 410 may be one of a fluorescent emitting layer, a phosphor-sensitized fluorescence emitting layer and a hyper-fluorescence emitting layer.

The second blue EML 450 in the second emitting part ST2 includes a first blue emitting layer 460, which is closer to the first electrode 210 as an anode, and a second blue emitting layer 470, which is closer to the second electrode 230 as a cathode. The second blue emitting layer 470 contacts and is disposed on the first blue emitting layer 460 so that the second blue EML 450 has a double-layered structure.

The first blue emitting layer 460 includes a first phosphorescent compound 466. In addition, the first blue emitting layer 460 may further include a first p-type host 462 and a first n-type host 464. The first blue emitting layer 460 is a phosphorescent emitting layer.

The first phosphorescent compound 466 serves as an emitter (e.g., dopant) so that the blue light is provided (emitted) from the first phosphorescent compound 466. An exciplex can be generated by the first p-type host 462 and the first n-type host 464.

The second blue emitting layer 470 includes a second phosphorescent compound 476 and a fluorescent compound 478. In addition, the second blue emitting layer 470 may further include a second p-type host 472 and a second n-type host 474. The second blue emitting layer 470 is a phosphor-sensitized fluorescence (PSF) emitting layer.

The fluorescent compound 478 serves as an emitter (e.g., dopant) so that the blue light is provided (emitted) from the fluorescent compound 478. An energy may be transferred into the fluorescent compound 478 by the second phosphorescent compound 476. The second phosphorescent compound 476 may be referred to as an auxiliary dopant or auxiliary host. An exciplex can be generated by the second p-type host 472 and the second n-type host 474.

Each of the first p-type host 462 in the first blue emitting layer 460 and the second p-type host 472 in the second blue emitting layer 470 is a compound represented by Formula 1. For example, each of the first p-type host 462 in the first blue emitting layer 460 and the second p-type host 472 in the second blue emitting layer 470 may be independently selected from the compounds in Formula 2.

Each of the first n-type host 464 in the first blue emitting layer 460 and the second n-type host 474 in the second blue emitting layer 470 is a compound represented by Formula 3. For example, each of the first n-type host 464 in the first blue emitting layer 460 and the second n-type host 474 in the second blue emitting layer 470 may be independently selected from the compounds in Formula 4.

Each of the first phosphorescent compound 466 in the first blue emitting layer 460 and the second phosphorescent compound 476 in the second blue emitting layer 470 is a compound represented by Formula 5. For example, each of the first phosphorescent compound 466 in the first blue emitting layer 460 and the second phosphorescent compound 476 in the second blue emitting layer 470 may be independently selected from the compounds in Formula 6.

The fluorescent compound 478 is a compound represented by Formula 7. For example, the fluorescent compound 478 may be one of the compounds in Formula 8.

The second blue EML 450 may have a thickness of 10 to 100 nm, and each of the first and second blue emitting layers 460 and 470 may have a thickness of 5 to 95 nm, preferably 5 to 50 nm. A thickness of the first blue emitting layer 460 and a thickness of the second blue emitting layer 470 may be same or different.

In an aspect of the present disclosure, the thickness of the first blue emitting layer 460 may be smaller than that of the second blue emitting layer 470. In this case, the emitting efficiency of the OLED D3 is further improved. For example, the first blue emitting layer 460 may have a thickness of 5 to 15 nm, and the second blue emitting layer 470 may have a thickness of 15 to 25 nm.

In the first blue emitting layer 460, a weight % of each of the first p-type host 462 and a weight % of the first n-type host 464 is greater than that of the first phosphorescent compound 466. The weight % of the first p-type host 462 and the weight % of the first n-type host 464 may be same or different. For example, in the first blue emitting layer 460, the first p-type host 462 and the first n-type host 464 may have the same weight %, and each of the first p-type host 462 and the first n-type host 464 may have a part by weight of 200 to 600 with respect to 100 parts by weight of the first phosphorescent compound 466.

For example, in the first blue emitting layer 460, a summation of a weight % of the first p-type host 462, a weight % of the first n-type host 464 and a weight % of the first phosphorescent compound 466 may be 100%.

In the second blue emitting layer 470, a weight % of the second phosphorescent compound 476 is smaller than that of each of the second p-type host 472 and the second n-type host 474 and greater than that of the fluorescent compound 478. The weight % the second p-type host 472 and the weight % of the second n-type host 474 may be same or different. For example, in the second blue emitting layer 470, the second p-type host 472 and the second n-type host 474 may have the same weight %. With respect to 100 parts by weight of the fluorescent compound 478, each of the second p-type host 472 and the second n-type host 474 may have a part by weight of 5000 to 15000, and the second phosphorescent dopant 476 may have a part by weight of 1000 to 3000.

For example, in the second blue emitting layer 470, a summation of a weight % of the second p-type host 472, a weight % of the second n-type host 474, a weight % of the second phosphorescent compound 476 and a weight % of the fluorescent compound 478 may be 100%.

In the blue pixel region, the organic light emitting layer 220 of the OLED D3 includes the first blue EML 410 and the second blue EML 450 to have a tandem structure.

The second blue EML 450 includes the first blue emitting layer 460, which includes the first p-type host 462, the first n-type host 464 and the first phosphorescent compound 466, and the second blue emitting layer 470, which includes the second p-type host 472, the second n-type host 474, the second phosphorescent compound 476 and the fluorescent compound 478. Each of the first and second p-type hosts 462 and 472 is a compound represented by Formula 1, and each of the first and second n-type hosts 464 and 474 is a compound represented by Formula 3. Each of the first and second phosphorescent compounds 466 and 476 is represented by Formula 5, and the fluorescent compound 478 is represented by Formula 7.

Accordingly, the OLED D3 and the organic light emitting display device 100 of the present disclosure have advantages in the emitting efficiency and the color purity.

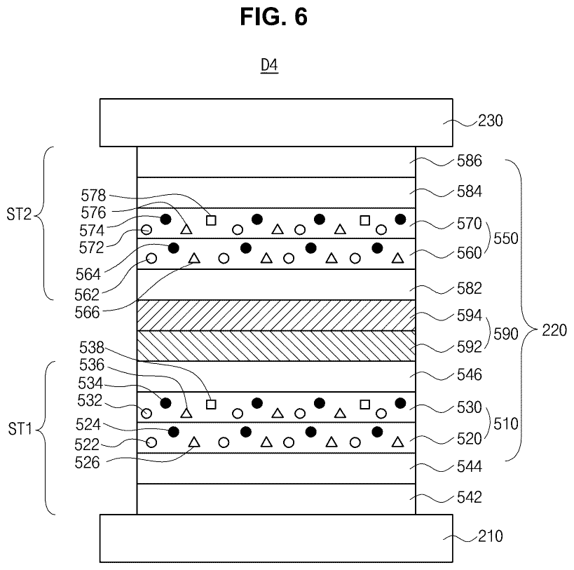

FIG. 6 is a schematic cross-sectional view of an OLED according to a fifth embodiment of the present disclosure.

As illustrated in FIG. 6, the OLED D4 includes first and second electrodes 210 and 230 facing each other and an organic light emitting layer 220 therebetween. The organic light emitting layer 220 includes a first emitting part ST1 including a first blue EML 510 and a second emitting part ST2 including a second blue EML 550. The organic light emitting layer 220 may include a CGL 590 between the first and second emitting parts ST1 and ST2. The OLED D4 in a top-emission type may further include a capping layer on the second electrode 230 to enhance a light extraction efficiency.

The organic light emitting display device 100 may include a red pixel region, a green pixel region and a blue pixel region, and the OLED D4 may be positioned in the blue pixel region.

The first electrode 210 is an anode, and the second electrode 230 is a cathode. One of the first and second electrodes 210 and 230 may be a reflective electrode, and the other one of the first and second electrodes 210 and 230 may be a transparent (or a semi-transparent) electrode.

In a top-emission type OLED D4, the first electrode 210 may be a reflective electrode and may have a structure of ITO/Ag/ITO, and the second electrode 230 may be a transparent electrode and may be formed of Mg:Ag with a weight % ratio of 1:9.

In a bottom-emission type OLED D4, the first electrode 210 may be a transparent electrode and may be formed of ITO, and the second electrode 230 may be a reflective electrode and may be formed of A1.

The first emitting part ST1 may further include at least one of a first HTL 544 under the first blue EML 510 and a first ETL 546 over the first blue EML 510.

In addition, the first emitting part ST1 may further include an HIL 542 between the first electrode 210 and the first HTL 544.

Moreover, the first emitting part ST1 may further include at least one of a first EBL between the first HTL 544 and the first blue EML 510 and a first HBL between the first blue EML 510 and the first ETL 546.

The second emitting part ST2 may further include at least one of a second HTL 582 under the second blue EML 550 and a second ETL 584 over the second blue EML 550.

In addition, the second emitting part ST2 may further include an EIL 586 between the second electrode 230 and the second ETL 584.

Moreover, the second emitting part ST2 may further include at least one of a second EBL between the second HTL 582 and the second blue EML 550 and a second HBL between the second blue EML 550 and the second ETL 584.

For example, the HIL 542 may include the above-mentioned hole injection material and may have a thickness of 1 to 30 nm, preferably 5 to 15 nm.

Each of the first and second HTLs 544 and 582 may include the above-mentioned hole transporting material and may have a thickness of 5 to 150 nm.

Each of the first and second ETLs 546 and 584 may include the above-mentioned electron transporting material and may have a thickness of 10 to 100 nm, preferably 20 to 40 nm.

The EIL 586 may include the above-mentioned electron injection material and may have a thickness of 0.1 to 10 nm, preferably 0.5 to 2 nm.

Each of the first and second EBLs may include the above-mentioned electron blocking material and may have a thickness of 5 to 40 nm, preferably 10 to 20 nm.

Each of the first and second HBLs may include the above-mentioned hole blocking material and may have a thickness of 1 to 20 nm, preferably 1 to 10 nm.

The CGL 590 is positioned between the first and second emitting parts ST1 and ST2. Namely, the first and second emitting parts ST1 and ST2 is connected to each other through the CGL 590. The CGL 590 may be a PN-junction CGL of an N-type CGL 592 and a P-type CGL 594.

The N-type CGL 592 is positioned between the first ETL 546 and the second HTL 582, and the P-type CGL 594 is positioned between the N-type CGL 592 and the second HTL 582.

The N-type CGL 592 provides an electron into the first blue EML 510 of the first emitting part ST1, and the P-type CGL 594 provides a hole into the second blue EML 550 of the second emitting part ST2.

The N-type CGL 592 may include the above-mentioned N-type charge generation material, and the P-type CGL 594 may include the above-mentioned P-type charge generation material.

The capping layer may include the above-mentioned hole transporting material and may have a thickness of 50 to 100 nm, preferably 70 to 80 nm.

The first blue EML 510 includes a first blue emitting layer 520, which is closer to the first electrode 210 as an anode, and a second blue emitting layer 530, which is closer to the second electrode 230 as a cathode. The second blue emitting layer 530 contacts and is disposed on the first blue emitting layer 520 so that the first blue EML 510 has a double-layered structure.

The first blue emitting layer 520 includes a first phosphorescent compound 526. In addition, the first blue emitting layer 520 may further include a first p-type host 522 and a first n-type host 524. The first blue emitting layer 520 is a phosphorescent emitting layer.

The first phosphorescent compound 526 serves as an emitter (e.g., dopant) so that the blue light is provided (emitted) from the first phosphorescent compound 526. An exciplex can be generated by the first p-type host 522 and the first n-type host 524.

The second blue emitting layer 530 includes a second phosphorescent compound 536 and a first fluorescent compound 538. In addition, the second blue emitting layer 530 may further include a second p-type host 532 and a second n-type host 534. The second blue emitting layer 530 is a phosphor-sensitized fluorescence (PSF) emitting layer.

The first fluorescent compound 538 serves as an emitter (e.g., dopant) so that the blue light is provided (emitted) from the first fluorescent compound 538. An energy may be transferred into the first fluorescent compound 538 by the second phosphorescent compound 536. The second phosphorescent compound 536 may be referred to as an auxiliary dopant or auxiliary host. An exciplex can be generated by the second p-type host 532 and the second n-type host 534.

Each of the first p-type host 522 in the first blue emitting layer 520 and the second p-type host 532 in the second blue emitting layer 530 is a compound represented by Formula 1. For example, each of the first p-type host 522 in the first blue emitting layer 520 and the second p-type host 532 in the second blue emitting layer 530 may be independently selected from the compounds in Formula 2.

Each of the first n-type host 524 in the first blue emitting layer 520 and the second n-type host 534 in the second blue emitting layer 530 is a compound represented by Formula 3. For example, each of the first n-type host 524 in the first blue emitting layer 520 and the second n-type host 534 in the second blue emitting layer 530 may be independently selected from the compounds in Formula 4.

Each of the first phosphorescent compound 526 in the first blue emitting layer 520 and the second phosphorescent compound 536 in the second blue emitting layer 530 is a compound represented by Formula 5. For example, each of the first phosphorescent compound 526 in the first blue emitting layer 520 and the second phosphorescent compound 536 in the second blue emitting layer 530 may be independently selected from the compounds in Formula 6.

The first fluorescent compound 538 is a compound represented by Formula 7. For example, the first fluorescent compound 538 may be one of the compounds in Formula 8.

The first blue EML 510 may have a thickness of 10 to 100 nm, and each of the first and second blue emitting layers 520 and 530 may have a thickness of 5 to 95 nm, preferably 5 to 50 nm. A thickness of the first blue emitting layer 520 and a thickness of the second blue emitting layer 530 may be same or different.

In an aspect of the present disclosure, the thickness of the first blue emitting layer 520 may be smaller than that of the second blue emitting layer 530. In this case, the emitting efficiency of the OLED D4 is further improved. For example, the first blue emitting layer 520 may have a thickness of 5 to 15 nm, and the second blue emitting layer 530 may have a thickness of 15 to 25 nm.

In the first blue emitting layer 520, a weight % of each of the first p-type host 522 and a weight % of the first n-type host 524 is greater than that of the first phosphorescent compound 526. The weight % of the first p-type host 522 and the weight % of the first n-type host 524 may be same or different. For example, in the first blue emitting layer 520, the first p-type host 522 and the first n-type host 524 may have the same weight %, and each of the first p-type host 522 and the first n-type host 524 may have a part by weight of 200 to 600 with respect to 100 parts by weight of the first phosphorescent compound 526.

For example, in the first blue emitting layer 520, a summation of a weight % of the first p-type host 522, a weight % of the first n-type host 524 and a weight % of the first phosphorescent compound 526 may be 100%.

In the second blue emitting layer 530, a weight % of the second phosphorescent compound 536 is smaller than that of each of the second p-type host 532 and the second n-type host 534 and greater than that of the first fluorescent compound 538. The weight % the second p-type host 532 and the weight % of the second n-type host 534 may be same or different. For example, in the second blue emitting layer 530, the second p-type host 532 and the second n-type host 534 may have the same weight %. With respect to 100 parts by weight of the first fluorescent compound 538, each of the second p-type host 532 and the second n-type host 534 may have a part by weight of 5000 to 15000, and the second phosphorescent dopant 536 may have a part by weight of 1000 to 3000.

For example, in the second blue emitting layer 530, a summation of a weight % of the second p-type host 532, a weight % of the second n-type host 534, a weight % of the second phosphorescent compound 536 and a weight % of the first fluorescent compound 538 may be 100%.

The second blue EML 550 in the second emitting part ST2 includes a third blue emitting layer 560, which is closer to the first electrode 210 as an anode, and a fourth blue emitting layer 570, which is closer to the second electrode 230 as a cathode. The fourth blue emitting layer 570 contacts and is disposed on the third blue emitting layer 560 so that the second blue EML 550 has a double-layered structure.

The third blue emitting layer 560 includes a third phosphorescent compound 566. In addition, the third blue emitting layer 560 may further include a third p-type host 562 and a third n-type host 564. The third blue emitting layer 560 is a phosphorescent emitting layer.

The third phosphorescent compound 566 serves as an emitter (e.g., dopant) so that the blue light is provided (emitted) from the third phosphorescent compound 566. An exciplex can be generated by the third p-type host 562 and the third n-type host 564.

The fourth blue emitting layer 570 includes a fourth phosphorescent compound 576 and a second fluorescent compound 578. In addition, the fourth blue emitting layer 570 may further include a fourth p-type host 572 and a fourth n-type host 574. The fourth blue emitting layer 570 is a phosphor-sensitized fluorescence (PSF) emitting layer.

The second fluorescent compound 578 serves as an emitter (e.g., dopant) so that the blue light is provided (emitted) from the second fluorescent compound 578. An energy may be transferred into the second fluorescent compound 578 by the fourth phosphorescent compound 576. The fourth phosphorescent compound 576 may be referred to as an auxiliary dopant or auxiliary host. An exciplex can be generated by the fourth p-type host 572 and the fourth n-type host 574.

Each of the third p-type host 562 in the third blue emitting layer 560 and the fourth p-type host 572 in the fourth blue emitting layer 570 is a compound represented by Formula 1. For example, each of the third p-type host 562 in the third blue emitting layer 560 and the fourth p-type host 572 in the fourth blue emitting layer 570 may be independently selected from the compounds in Formula 2.

Each of the third n-type host 564 in the third blue emitting layer 560 and the fourth n-type host 574 in the fourth blue emitting layer 570 is a compound represented by Formula 3. For example, each of the third n-type host 564 in the third blue emitting layer 560 and the fourth n-type host 574 in the fourth blue emitting layer 570 may be independently selected from the compounds in Formula 4.

Each of the third phosphorescent compound 566 in the third blue emitting layer 560 and the fourth phosphorescent compound 576 in the fourth blue emitting layer 570 is a compound represented by Formula 5. For example, each of the third phosphorescent compound 566 in the third blue emitting layer 560 and the fourth phosphorescent compound 576 in the fourth blue emitting layer 570 may be independently selected from the compounds in Formula 6.

The second fluorescent compound 578 is a compound represented by Formula 7. For example, the second fluorescent compound 578 may be one of the compounds in Formula 8.

The second blue EML 550 may have a thickness of 10 to 100 nm, and each of the third and fourth blue emitting layers 560 and 570 may have a thickness of 5 to 95 nm, preferably 5 to 50 nm. A thickness of the third blue emitting layer 560 and a thickness of the fourth blue emitting layer 570 may be same or different.

In an aspect of the present disclosure, the thickness of the third blue emitting layer 560 may be smaller than that of the fourth blue emitting layer 570. In this case, the emitting efficiency of the OLED D4 is further improved. For example, the third blue emitting layer 560 may have a thickness of 5 to 15 nm, and the fourth blue emitting layer 570 may have a thickness of 15 to 25 nm.

In the third blue emitting layer 560, a weight % of each of the third p-type host 562 and a weight % of the third n-type host 564 is greater than that of the third phosphorescent compound 566. The weight % of the third p-type host 562 and the weight % of the third n-type host 564 may be same or different. For example, in the third blue emitting layer 560, the third p-type host 562 and the third n-type host 564 may have the same weight %, and each of the third p-type host 562 and the third n-type host 564 may have a part by weight of 200 to 600 with respect to 100 parts by weight of the third phosphorescent compound 566.

For example, in the third blue emitting layer 560, a summation of a weight % of the third p-type host 562, a weight % of the third n-type host 564 and a weight % of the third phosphorescent compound 566 may be 100%.

In the fourth blue emitting layer 570, a weight % of the fourth phosphorescent compound 576 is smaller than that of each of the fourth p-type host 572 and the fourth n-type host 574 and greater than that of the second fluorescent compound 578. The weight % the fourth p-type host 572 and the weight % of the fourth n-type host 574 may be same or different. For example, in the fourth blue emitting layer 570, the fourth p-type host 572 and the fourth n-type host 574 may have the same weight %. With respect to 100 parts by weight of the second fluorescent compound 578, each of the fourth p-type host 572 and the fourth n-type host 574 may have a part by weight of 5000 to 15000, and the fourth phosphorescent dopant 576 may have a part by weight of 1000 to 3000.

For example, in the fourth blue emitting layer 570, a summation of a weight % of the fourth p-type host 572, a weight % of the fourth n-type host 574, a weight % of the fourth phosphorescent compound 576 and a weight % of the second fluorescent compound 578 may be 100%.

In the blue pixel region, the organic light emitting layer 220 of the OLED D4 includes the first blue EML 510 and the second blue EML 550 to have a tandem structure.

The first blue EML 510 includes the first blue emitting layer 520, which includes the first p-type host 522, the first n-type host 524 and the first phosphorescent compound 526, and the second blue emitting layer 530, which includes the second p-type host 532, the second n-type host 534, the second phosphorescent compound 536 and the first fluorescent compound 538. Each of the first and second p-type hosts 522 and 532 is a compound represented by Formula 1, and each of the first and second n-type hosts 524 and 534 is a compound represented by Formula 3. Each of the first and second phosphorescent compounds 526 and 536 is represented by Formula 5, and the first fluorescent compound 538 is represented by Formula 7.

The second blue EML 550 includes the third blue emitting layer 560, which includes the third p-type host 562, the third n-type host 564 and the third phosphorescent compound 566, and the fourth blue emitting layer 570, which includes the fourth p-type host 572, the fourth n-type host 574, the fourth phosphorescent compound 576 and the second fluorescent compound 578. Each of the third and fourth p-type hosts 562 and 572 is a compound represented by Formula 1, and each of the third and fourth n-type hosts 564 and 574 is a compound represented by Formula 3. Each of the third and fourth phosphorescent compounds 566 and 576 is represented by Formula 5, and the second fluorescent compound 578 is represented by Formula 7.

Accordingly, the OLED D4 and the organic light emitting display device 100 of the present disclosure have advantages in the emitting efficiency and the color purity.

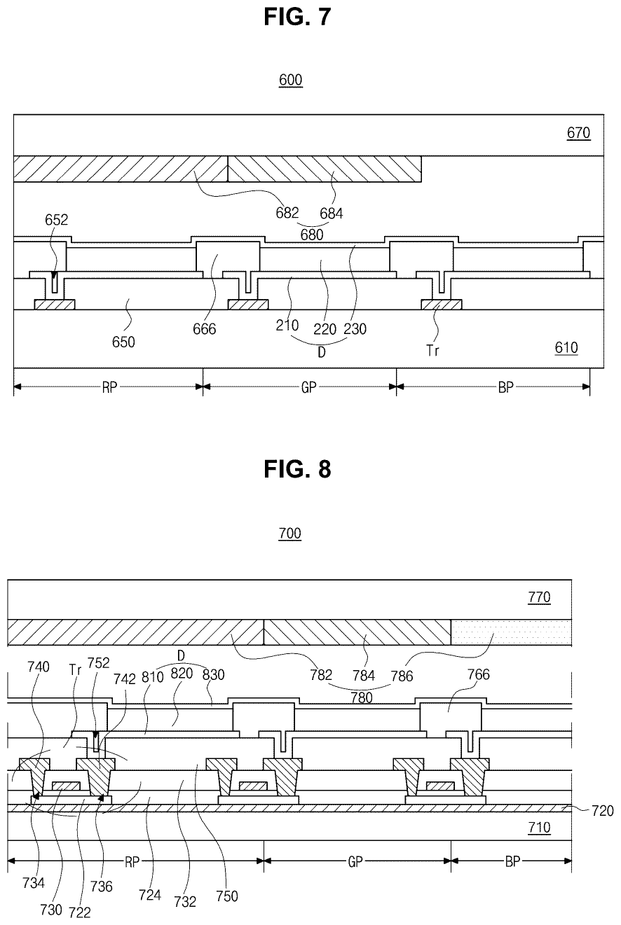

FIG. 7 is a schematic cross-sectional view illustrating an organic light emitting display device according to a sixth embodiment of the present disclosure.

As illustrated in FIG. 7, the organic light emitting display device 600 includes a first substrate 610, where a red pixel region RP, a green pixel region GP and a blue pixel region BP are defined, a second substrate 670 facing the first substrate 610, an OLED D, which is positioned between the first and second substrates 610 and 670 and providing blue emission, and a color conversion layer 680 between the OLED D and the second substrate 670.

Although not shown, a color filter may be formed between the second substrate 670 and each color conversion layer 680.

Each of the first and second substrates 610 and 670 may be a glass substrate or a flexible substrate. For example, the flexible substrate may be a polyimide (PI) substrate, a polyethersulfone (PES) substrate, a polyethylenenaphthalate (PEN) substrate, a polyethylene terephthalate (PET) substrate or a polycarbonate (PC) substrate.

A TFT Tr, which corresponding to each of the red, green and blue pixel regions RP, GP and BP, is formed on the first substrate 610, and a planarization layer 650, which has a drain contact hole 652 exposing an electrode, e.g., a drain electrode, of the TFT Tr is formed to cover the TFT Tr.

The OLED D including a first electrode 210, an organic light emitting layer 220 and a second electrode 230 is formed on the planarization layer 650. In this instance, the first electrode 210 may be connected to the drain electrode of the TFT Tr through the drain contact hole 652.

The first electrode 210 may be an anode, and the second electrode 230 may be a cathode. One of the first and second electrodes 210 and 230 may be a reflective electrode, and the other one of the first and second electrodes 210 and 230 may be a transparent (or a semi-transparent) electrode.

In a top-emission type OLED D, the first electrode 210 may be a reflective electrode and may have a structure of ITO/Ag/ITO, and the second electrode may be a transparent electrode and may be formed of Mg:Ag with a weight % ratio of 1:9. In a bottom-emission type OLED D, the first electrode 210 may be a transparent electrode and may be formed of ITO, and the second electrode may be a reflective electrode and may be formed of A1.

A bank layer 666 is formed on the planarization layer 650 to cover an edge of the first electrode 210. Namely, the bank layer 666 is positioned at a boundary of each of the red, green and blue pixel regions and exposes a center of the first electrode 210 in the pixel.

The OLED D emits a blue light and may have a structure shown in FIGS. 3 to 6. Namely, the OLED D is formed in each of the red, green and blue pixel regions RP, GP and BP and provides the blue light.

For example, referring to FIG. 3, the organic light emitting layer 220 of the OLED D includes the blue EML 240, and the blue EML 240 include the first blue emitting layer 250, which includes the first p-type host 252, the first n-type host 254 and the first phosphorescent compound 256, and the second blue emitting layer 260, which includes the second p-type host 262, the second n-type host 264, the second phosphorescent compound 266 and the fluorescent compound 268.

Each of the first p-type host 252 and the second p-type host 262 is a compound represented by Formula 1, and each of the first and second n-type hosts 254 and 264 is a compound represented by Formula 3. Each of the first and second phosphorescent compounds 256 and 266 is represented by Formula 5, and the fluorescent compound 268 is represented by Formula 7.

Since the OLED D emits blue light in each of the red, green and blue pixel regions RP, GP and BP, the organic light emitting layer 220 may be integrally formed as a common layer in the red, green and blue pixel regions RP, GP and BP without separation. The bank layer 666 may be formed to prevent a current leakage at an edge of the first electrode 210 and may be omitted.

The color conversion layer 680 includes a first color conversion layer 682 corresponding to the red pixel region RP and a second color conversion layer 684 corresponding to the green pixel region GP. For example, the color conversion layer 680 may include an inorganic color conversion material such as a quantum dot. The color conversion layer is not presented in the blue pixel region BP so that the OLED D in the blue pixel region BP may directly face the second substrate 670.

The blue light from the OLED D is converted into the red light by the first color conversion layer 682 in the red pixel region RP, and the blue light from the OLED D is converted into the green light by the second color conversion layer 684 in the green pixel region GP.

Accordingly, the organic light emitting display device 600 can display a full-color image.

When the light from the OLED D passes through the first substrate 610 to display an image, the color conversion layer 680 may be disposed between the OLED D and the first substrate 610.

FIG. 8 is a schematic cross-sectional view illustrating an organic light emitting display device according to a seventh embodiment of the present disclosure.

As illustrated in FIG. 8, the organic light emitting display device 700 includes a first substrate 710, where a red pixel region RP, a green pixel region GP and a blue pixel region BP are defined, a second substrate 770 facing the first substrate 710, an OLED D, which is positioned between the first and second substrates 710 and 770 and providing white emission, and a color filter layer 780 between the OLED D and the second substrate 770.

Each of the first and second substrates 710 and 770 may be a glass substrate or a flexible substrate. For example, the flexible substrate may be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 720 is formed on the substrate, and the TFT Tr corresponding to each of the red, green and blue pixel regions RP, GP and BP is formed on the buffer layer 720. The buffer layer 720 may be omitted.

A semiconductor layer 722 is formed on the buffer layer 720. The semiconductor layer 722 may include an oxide semiconductor material or polycrystalline silicon.

A gate insulating layer 724 is formed on the semiconductor layer 722. The gate insulating layer 724 may be formed of an inorganic insulating material such as silicon oxide or silicon nitride.

A gate electrode 730, which is formed of a conductive material, e.g., metal, is formed on the gate insulating layer 724 to correspond to a center of the semiconductor layer 722.

An interlayer insulating layer 732, which is formed of an insulating material, is formed on the gate electrode 730. The interlayer insulating layer 732 may be formed of an inorganic insulating material, e.g., silicon oxide or silicon nitride, or an organic insulating material, e.g., benzocyclobutene or photo-acryl.

The interlayer insulating layer 732 includes first and second contact holes 734 and 736 exposing both sides of the semiconductor layer 722. The first and second contact holes 734 and 736 are positioned at both sides of the gate electrode 730 to be spaced apart from the gate electrode 730.

A source electrode 740 and a drain electrode 742, which are formed of a conductive material, e.g., metal, are formed on the interlayer insulating layer 732.

The source electrode 740 and the drain electrode 742 are spaced apart from each other with respect to the gate electrode 730 and respectively contact both sides of the semiconductor layer 722 through the first and second contact holes 734 and 736.

The semiconductor layer 722, the gate electrode 730, the source electrode 740 and the drain electrode 742 constitute the TFT Tr. The TFT Tr serves as a driving element. Namely, the TFT Tr may correspond to the driving TFT Td (of FIG. 1).

Although not shown, the gate line and the data line cross each other to define the pixel regions, and the switching TFT is formed to be connected to the gate and data lines. The switching TFT is connected to the TFT Tr as the driving element.

In addition, the power line, which may be formed to be parallel to and spaced apart from one of the gate and data lines, and the storage capacitor for maintaining the voltage of the gate electrode of the TFT Tr in one frame may be further formed.

A planarization layer 750, which includes a drain contact hole 752 exposing the drain electrode 742 of the TFT Tr, is formed to cover the TFT Tr.

A first electrode 810, which is connected to the drain electrode 742 of the TFT Tr through the drain contact hole 752, is separately formed in each pixel and on the planarization layer 750. The first electrode 810 may be an anode and may be formed of a conductive material having a relatively high work function. For example, the first electrode 810 may include a transparent conductive oxide layer formed of a transparent conductive oxide (TCO) and a reflective layer.

For example, the transparent conductive oxide material layer of the first electrode 810 may be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

For example, the reflective layer may be formed of one of silver (Ag), an alloy of Ag and one of palladium (Pd), copper (Cu), indium (In) and neodymium (Nd), and aluminum-palladium-copper (APC) alloy. For example, the first electrode 210 may have a double-layered structure of Ag/ITO or APC/ITO or a triple-layered structure of ITO/Ag/ITO or ITO/APC/ITO.

A bank layer 766 is formed on the planarization layer 750 to cover an edge of the first electrode 810. Namely, the bank layer 766 is positioned at a boundary of the pixel and exposes a center of the first electrode 810 in the pixel. Since the OLED D emits blue light in each of the red, green and blue pixel regions RP, GP and BP, the organic light emitting layer 820 may be integrally formed as a common layer in the red, green and blue pixel regions RP, GP and BP without separation. The bank layer 766 may be formed to prevent a current leakage at an edge of the first electrode 810 and may be omitted.

An organic emitting layer 820 is formed on the first electrode 810.

A second electrode 830 is formed over the first substrate 710 where the organic emitting layer 820 is formed.

In the organic light emitting display device 700, since the light emitted from the organic emitting layer 820 is incident to the color filter layer 780 through the second electrode 830, the second electrode 830 has a thin profile for transmitting the light.

The first electrode 810, the organic emitting layer 820 and the second electrode 830 constitute the OLED D.

The color filter layer 780 is disposed over the OLED D and includes a red color filter 782, a green color filter 784 and a blue color filter 786 respectively corresponding to the red pixel region RP, the green pixel region GP and the blue pixel region BP. The red color filter 782 includes at least one of a red dye and a red pigment, the green color filter 784 includes at least one of a green dye and a green pigment, and the blue color filter 786 includes at least one of a blue dye and a blue pigment.

The color filter layer 780 may be attached to the OLED D using an adhesive layer. Alternatively, the color filter layer 780 may be formed directly on the OLED D. When an encapsulation layer (or an encapsulation film) is formed to cover the OLED D, the color filter layer 780 may be formed on the encapsulation layer.

An encapsulation layer (or an encapsulation film) may be formed to prevent penetration of moisture into the OLED D. For example, the encapsulation film may include a first inorganic insulating layer, an organic insulating layer and a second inorganic insulating layer sequentially stacked, but it is not limited thereto. The encapsulation film may be omitted.

A polarization plate for reducing an ambient light reflection may be disposed over an outer side of the second substrate 770 in the top-emission type OLED D. For example, the polarization plate may be a circular polarization plate.

In the OLED D of FIG. 8, the first electrode 810 and the second electrode 830 are a reflective electrode and a transparent (a semitransparent) electrode, respectively, and the color filter layer 780 is disposed over the OLED D.

Alternatively, the first electrode 810 and the second electrode 830 may be a transparent (a semitransparent) electrode and a reflective electrode, respectively, and the color filter layer 780 may be disposed between the OLED D and the first substrate 710. In this case, first electrode 810 may have a single-layered structure of the transparent conductive oxide layer.

A color conversion layer may be formed between the OLED D and the color filter layer 780. The color conversion layer may include a red color conversion layer, a green color conversion layer and a blue color conversion layer respectively corresponding to the red, green and blue pixel regions RP, GP and BP. The white light from the OLED D is converted into the red light, the green light and the blue light by the red, green and blue color conversion layer, respectively.

The color conversion layer may be included instead of the color filter layer 780.

As described above, in the organic light emitting display device 700, the OLED D in the red, green and blue pixel regions RP, GP and BP emits the white light, and the white light from the organic light emitting diode D passes through the red color filter 782, the green color filter 784 and the blue color filter 786. As a result, the red light, the green light and the blue light are provided from the red pixel region RP, the green pixel region GP and the blue pixel region BP, respectively.

In FIG. 8, the OLED D emitting the white light is used for a display device. Alternatively, the OLED D may be formed on an entire surface of a substrate without at least one of the driving element and the color filter layer to be used for a lightening device. The display device and the lightening device each including the OLED D of the present disclosure may be referred to as an organic light emitting device.

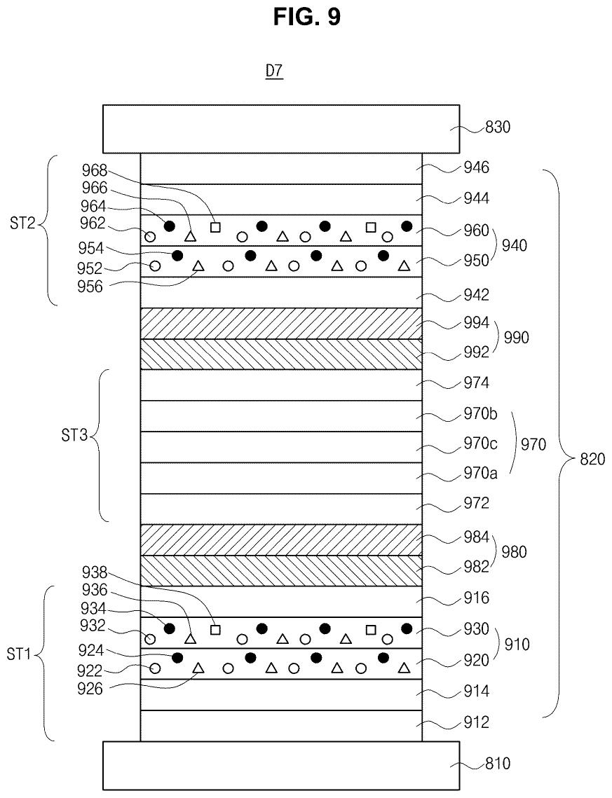

FIG. 9 is a schematic cross-sectional view of an OLED according to an eighth embodiment of the present disclosure.

As illustrated in FIG. 9, the OLED D7 includes first and second electrodes 810 and 830, which face each other and an organic light emitting layer 820 therebetween. The organic light emitting layer 820 includes a first emitting part ST1 including a first EML, e.g., a first blue EML, 910, a second emitting part ST2 including a second EML, e.g., a second blue EML, 940, and a third emitting part ST3 including a third EML 970. The organic light emitting layer 820 may further includes a first CGL 980 between the first and third emitting parts ST1 and ST3 and a second CGL 990 between the second and third emitting parts ST2 and ST3. The OLED D7 in a top-emission type may further include a capping layer on the second electrode 830 to enhance a light extraction efficiency.

The organic light emitting display device 700 may include a red pixel region RP, a green pixel region GP and a blue pixel region BP, and the OLED D7 may be positioned in the red, green and blue pixel regions RP, GP and BP and emits white light.

The first electrode 810 is an anode, and the second electrode 830 is a cathode. One of the first and second electrodes 810 and 830 may be a reflective electrode, and the other one of the first and second electrodes 810 and 830 may be a transparent (or a semi-transparent) electrode.

In a top-emission type OLED D7, the first electrode 810 may be a reflective electrode and may have a structure of ITO/Ag/ITO, and the second electrode 830 may be a transparent electrode and may be formed of Mg:Ag with a weight % ratio of 1:9.

In a bottom-emission type OLED D7, the first electrode 810 may be a transparent electrode and may be formed of ITO, and the second electrode 830 may be a reflective electrode and may be formed of Al.

The first emitting part ST1 may further include at least one of a first HTL 914 under the first blue EML 910 and a first ETL 916 over the first blue EML 910.

In addition, the first emitting part ST1 may further include an HIL 912 between the first electrode 810 and the first HTL 914.

Moreover, the first emitting part ST1 may further include at least one of a first EBL between the first HTL 914 and the first blue EML 910 and a first HBL between the first blue EML 910 and the first ETL 916.

The second emitting part ST2 may further include at least one of a second HTL 942 under the second blue EML 940 and a second ETL 944 over the second blue EML 940.

In addition, the second emitting part ST2 may further include an EIL 946 between the second electrode 830 and the second ETL 944.

Moreover, the second emitting part ST2 may further include at least one of a second EBL between the second HTL 942 and the second EML 940 and a second HBL between the second EML 940 and the second ETL 944.

In the third emitting part ST3, the third EML 970 may include a red EML 970a, a yellow-green EML 970c and a green EML 970b. In this case, the yellow-green EML 970c is disposed between the red and green EMLs 970a and 970b. Alternatively, the yellow-green EML 970c may be omitted, and the third EML 970 may have a double-layered structure including the red and green EMLs 970a and 970b.

The red EML 970a includes a red host and a red dopant, the green EML 970b includes a green host and a green dopant, and the yellow-green EML 970c includes a yellow-green host and a yellow-green dopant. Each of the red dopant, the green dopant and the yellow-green dopant may be one of a fluorescent compound, a phosphorescent compound and a delayed fluorescent compound.

For example, the red host may be selected from the group consisting of mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbiphenyl (CDBP), 2,7-bis(carbazole-9-yl)-9,9-dimethylfluorene (DMFL-CBP), 2,2′,7,7′-tetrakis(carbazole-9-yl)-9,9-spiorofluorene (Spiro-CBP), and 3,6-bis(carbazole-9-yl)-9-(2-ethyl-hexyl)-9H-carbazole (TCzl), but it is not limited thereto.

The red dopant may be selected from the group consisting of[bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)2(acac)), tris[2-(4-n-hexylphenyl)quinoline]iridium(III) (Hex-Ir(phq)3), tris[2-phenyl-4-methylquinoline]iridium(III) (Ir(Mphq)3), bis(2-phenylquinoline)(2,2,6,6-tetramethylheptene-3,5-dionate)iridium(III) (Ir(dpm)PQ2), bis(phenylisoquinoline)(2,2,6,6-tetramethylheptene-3,5-dionate)iridium(III) (Ir(dpm)(piq)2), bis[(4-n-hexylphenyl)isoquinoline](acetylacetonate)iridium(III) (Hex-Ir(piq)2(acac)), tris[2-(4-n-hexylphenyl)quinoline]iridium(III) (Hex-Ir(piq)3), tris(2-(3-methylphenyl)-7-methyl-quinolato)iridium (Ir(dmpq)3), bis[2-(2-methylphenyl)-7-methyl-quinoline](acetylacetonate)iridium(III) (Ir(dmpq)2(acac)), bis[2-(3,5-dimethylphenyl)-4-methyl-quinoline](acetylacetonate)iridium(III) (Ir(mphmq)2(acac)), and tris(dibenzoylmethane)mono(1,10-phenanthroline)europium(III) (Eu(dbm)3(phen)), but it is not limited thereto.

Each of the green host and the yellow-green host may be independently selected from the group consisting of mCP-CN, CBP, mCBP, mCP, DPEPO, 2,8-bis(diphenylphosphoryl)dibenzothiophene (PPT), TmPyPB, PYD-2Cz, 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto.

The green dopant may be selected from the group consisting of [bis(2-phenylpyridine)](pyridyl-2-benzofuro[2,3-b]pyridine)iridium), tris[2-phenylpyridine]iridium(III) (Ir(ppy)3), fac-tris(2-phenylpyridine)iridium(III) (fac-Ir(ppy)3), bis(2-phenylpyridine)(acetylacetonate)iridium(III) (Ir(ppy)2(acac)), tris[2-(p-tolyl)pyridine]iridium(III) (Ir(mppy)3), bis(2-(naphthalene-2-yl)pyridine)(acetylacetonate)iridium(III) (Ir(npy)2acac), tris(2-phenyl-3-methyl-pyridine)iidium (Ir(3mppy)3), and fac-tris(2-(3-p-xylyl)phenyl)pyridine iridium(III) (TEG), but it is not limited thereto.

The yellow-green dopant may be selected from the group consisting of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)irdium(III) (Ir(BT)2(acac)), bis(2-(9,9-diethytl-fluoren-2-yl)-1-phenyl-1H-benzo[d]imdiazolato)(acetylacetonate)iridium(III) (Ir(fbi)2(acac)), bis(2-phenylpyridine)(3-(pyridine-2-yl)-2H-chromen-2-onate)iridium(III) (fac-Ir(ppy)2Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(III) (PO-01), but it is not limited thereto.

The third emitting part ST3 may include at least one of a third HTL 972 under the third EML 970 and a third ETL 974 over the third EML 970.

In addition, the third emitting part ST3 may further include at least one of a third EBL between the third HTL 972 and the third EML 970 and a third HBL between the third EML 970 and the third ETL 974.

For example, the HIL 912 may include the above-mentioned hole injection material and may have a thickness of 1 to 30 nm, preferably 5 to 15 nm.

Each of the first to third HTLs 914, 942 and 972 may include the above-mentioned hole transporting material and may have a thickness of 5 to 150 nm.

Each of the first to third ETLs 916, 944 and 974 may include the above-mentioned electron transporting material and may have a thickness of 10 to 100 nm, preferably 20 to 40.

The EIL 946 may include the above-mentioned electron injection material and may have a thickness of 0.1 to 10 nm, preferably 0.5 to 2 nm.

Each of the first to third EBLs may include the above-mentioned electron blocking material and may have a thickness of 5 to 40 nm, preferably 10 to 20 nm.

Each of the first to third HBLs may include the above-mentioned hole blocking material and may have a thickness of 1 to 20 nm, preferably 1 to 10 nm.

The first CGL 980 is positioned between the first and third emitting parts ST1 and ST3, and the second CGL 990 is positioned between the second and third emitting parts ST2 and ST3. Namely, the first emitting part ST1, the first CGL 980, the third emitting part ST3, the second CGL 990 and the second emitting part ST2 are sequentially stacked on the first electrode 810. In other words, the first emitting part ST1 is positioned between the first electrode 810 and the first CGL 980, the third emitting part ST3 is positioned between the first and second CGLs 980 and 990, and the second emitting part ST2 is positioned between the second CGL 990 and the second electrode 830.

The first CGL 980 may be a P-N junction CGL of a first N-type CGL 982 and a first P-type CGL 984, and the second CGL 990 may be a P-N junction CGL of a second N-type CGL 992 and a second P-type CGL 994.

In the first CGL 980, the first N-type CGL 982 is positioned between the first ETL 916 and the third HTL 972, and the first P-type CGL 984 is positioned between the first N-type CGL 982 and the third HTL 972.

In the second CGL 990, the second N-type CGL 992 is positioned between the third ETL 974 and the second HTL 942, and the second P-type CGL 994 is positioned between the second N-type CGL 992 and the second HTL 942.

Each of the first and second N-type CGLs 982 and 992 may include the above-mentioned N-type charge generation material, and each of the first and second P-type CGLs 984 and 994 may include the above-mentioned P-type charge generation material.

The capping layer may include the above-mentioned hole transporting material and may have a thickness of 50 to 100 nm, preferably 70 to 80 nm.

The first blue EML 910 includes a first blue emitting layer 920, which is closer to the first electrode 810 as an anode, and a second blue emitting layer 930, which is closer to the second electrode 830 as a cathode. The second blue emitting layer 930 contacts and is disposed on the first blue emitting layer 920 so that the first blue EML 910 has a double-layered structure.

The first blue emitting layer 920 includes a first phosphorescent compound 926. In addition, the first blue emitting layer 920 may further include a first p-type host 922 and a first n-type host 924. The first blue emitting layer 920 is a phosphorescent emitting layer.

The first phosphorescent compound 926 serves as an emitter (e.g., dopant) so that the blue light is provided (emitted) from the first phosphorescent compound 926. An exciplex can be generated by the first p-type host 922 and the first n-type host 924.

The second blue emitting layer 930 includes a second phosphorescent compound 936 and a first fluorescent compound 938. In addition, the second blue emitting layer 930 may further include a second p-type host 932 and a second n-type host 934. The second blue emitting layer 930 is a phosphor-sensitized fluorescence (PSF) emitting layer.

The first fluorescent compound 938 serves as an emitter (e.g., dopant) so that the blue light is provided (emitted) from the first fluorescent compound 938. An energy may be transferred into the first fluorescent compound 938 by the second phosphorescent compound 936. The second phosphorescent compound 936 may be referred to as an auxiliary dopant or auxiliary host. An exciplex can be generated by the second p-type host 932 and the second n-type host 934.

Each of the first p-type host 922 in the first blue emitting layer 920 and the second p-type host 932 in the second blue emitting layer 930 is a compound represented by Formula 1. For example, each of the first p-type host 922 in the first blue emitting layer 920 and the second p-type host 932 in the second blue emitting layer 930 may be independently selected from the compounds in Formula 2.

Each of the first n-type host 924 in the first blue emitting layer 920 and the second n-type host 934 in the second blue emitting layer 930 is a compound represented by Formula 3. For example, each of the first n-type host 924 in the first blue emitting layer 920 and the second n-type host 934 in the second blue emitting layer 930 may be independently selected from the compounds in Formula 4.

Each of the first phosphorescent compound 926 in the first blue emitting layer 920 and the second phosphorescent compound 936 in the second blue emitting layer 930 is a compound represented by Formula 5. For example, each of the first phosphorescent compound 926 in the first blue emitting layer 920 and the second phosphorescent compound 936 in the second blue emitting layer 930 may be independently selected from the compounds in Formula 6.

The first fluorescent compound 938 is a compound represented by Formula 7. For example, the first fluorescent compound 938 may be one of the compounds in Formula 8.

The first blue EML 910 may have a thickness of 10 to 100 nm, and each of the first and second blue emitting layers 920 and 930 may have a thickness of 5 to 95 nm, preferably 5 to 50 nm. A thickness of the first blue emitting layer 920 and a thickness of the second blue emitting layer 930 may be same or different.

In an aspect of the present disclosure, the thickness of the first blue emitting layer 920 may be smaller than that of the second blue emitting layer 930. In this case, the emitting efficiency of the OLED D7 is further improved. For example, the first blue emitting layer 920 may have a thickness of 5 to 15 nm, and the second blue emitting layer 930 may have a thickness of 15 to 25 nm.

In the first blue emitting layer 920, a weight % of each of the first p-type host 922 and a weight % of the first n-type host 924 is greater than that of the first phosphorescent compound 926. The weight % of the first p-type host 922 and the weight % of the first n-type host 924 may be same or different. For example, in the first blue emitting layer 920, the first p-type host 922 and the first n-type host 924 may have the same weight %, and each of the first p-type host 922 and the first n-type host 924 may have a part by weight of 200 to 600 with respect to 100 parts by weight of the first phosphorescent compound 926.

For example, in the first blue emitting layer 920, a summation of a weight % of the first p-type host 922, a weight % of the first n-type host 924 and a weight % of the first phosphorescent compound 926 may be 100%.

In the second blue emitting layer 930, a weight % of the second phosphorescent compound 936 is smaller than that of each of the second p-type host 932 and the second n-type host 934 and greater than that of the first fluorescent compound 938. The weight % the second p-type host 932 and the weight % of the second n-type host 934 may be same or different. For example, in the second blue emitting layer 930, the second p-type host 932 and the second n-type host 934 may have the same weight %. With respect to 100 parts by weight of the first fluorescent compound 938, each of the second p-type host 932 and the second n-type host 934 may have a part by weight of 5000 to 15000, and the second phosphorescent dopant 936 may have a part by weight of 1000 to 3000.

For example, in the second blue emitting layer 930, a summation of a weight % of the second p-type host 932, a weight % of the second n-type host 934, a weight % of the second phosphorescent compound 936 and a weight % of the first fluorescent compound 938 may be 100%.

The second blue EML 940 in the second emitting part ST2 includes a third blue emitting layer 950, which is closer to the first electrode 810 as an anode, and a fourth blue emitting layer 960, which is closer to the second electrode 830 as a cathode. The fourth blue emitting layer 960 contacts and is disposed on the third blue emitting layer 950 so that the second blue EML 940 has a double-layered structure.

The third blue emitting layer 950 includes a third phosphorescent compound 956. In addition, the third blue emitting layer 950 may further include a third p-type host 952 and a third n-type host 954. The third blue emitting layer 950 is a phosphorescent emitting layer.

The third phosphorescent compound 956 serves as an emitter (e.g., dopant) so that the blue light is provided (emitted) from the third phosphorescent compound 956. An exciplex can be generated by the third p-type host 952 and the third n-type host 954.

The fourth blue emitting layer 960 includes a fourth phosphorescent compound 966 and a second fluorescent compound 968. In addition, the fourth blue emitting layer 960 may further include a fourth p-type host 962 and a fourth n-type host 964. The fourth blue emitting layer 960 is a phosphor-sensitized fluorescence (PSF) emitting layer.

The second fluorescent compound 968 serves as an emitter (e.g., dopant) so that the blue light is provided (emitted) from the second fluorescent compound 968. An energy may be transferred into the second fluorescent compound 968 by the fourth phosphorescent compound 966. The fourth phosphorescent compound 966 may be referred to as an auxiliary dopant or auxiliary host. An exciplex can be generated by the fourth p-type host 962 and the fourth n-type host 964.

Each of the third p-type host 952 in the third blue emitting layer 950 and the fourth p-type host 962 in the fourth blue emitting layer 960 is a compound represented by Formula 1. For example, each of the third p-type host 952 in the third blue emitting layer 950 and the fourth p-type host 962 in the fourth blue emitting layer 960 may be independently selected from the compounds in Formula 2.

Each of the third n-type host 954 in the third blue emitting layer 950 and the fourth n-type host 964 in the fourth blue emitting layer 960 is a compound represented by Formula 3. For example, each of the third n-type host 954 in the third blue emitting layer 950 and the fourth n-type host 964 in the fourth blue emitting layer 960 may be independently selected from the compounds in Formula 4.

Each of the third phosphorescent compound 956 in the third blue emitting layer 950 and the fourth phosphorescent compound 966 in the fourth blue emitting layer 960 is a compound represented by Formula 5. For example, each of the third phosphorescent compound 956 in the third blue emitting layer 950 and the fourth phosphorescent compound 966 in the fourth blue emitting layer 960 may be independently selected from the compounds in Formula 6.

The second fluorescent compound 968 is a compound represented by Formula 7. For example, the second fluorescent compound 968 may be one of the compounds in Formula 8.

The second blue EML 940 may have a thickness of 10 to 100 nm, and each of the first and second blue emitting layers 950 and 960 may have a thickness of 5 to 95 nm, preferably 5 to 50 nm. A thickness of the third blue emitting layer 950 and a thickness of the fourth blue emitting layer 960 may be same or different.

In an aspect of the present disclosure, the thickness of the third blue emitting layer 950 may be smaller than that of the fourth blue emitting layer 960. In this case, the emitting efficiency of the OLED D7 is further improved. For example, the third blue emitting layer 950 may have a thickness of 5 to 15 nm, and the fourth blue emitting layer 960 may have a thickness of 15 to 25 nm.

In the third blue emitting layer 950, a weight % of each of the third p-type host 952 and a weight % of the third n-type host 954 is greater than that of the third phosphorescent compound 956. The weight % of the third p-type host 952 and the weight % of the third n-type host 954 may be same or different. For example, in the third blue emitting layer 950, the third p-type host 952 and the third n-type host 954 may have the same weight %, and each of the third p-type host 952 and the third n-type host 954 may have a part by weight of 200 to 600 with respect to 100 parts by weight of the third phosphorescent compound 956.

For example, in the third blue emitting layer 950, a summation of a weight % of the third p-type host 952, a weight % of the third n-type host 954 and a weight % of the third phosphorescent compound 956 may be 100%.

In the fourth blue emitting layer 960, a weight % of the fourth phosphorescent compound 966 is smaller than that of each of the fourth p-type host 962 and the fourth n-type host 964 and greater than that of the second fluorescent compound 968. The weight % the fourth p-type host 962 and the weight % of the fourth n-type host 964 may be same or different. For example, in the fourth blue emitting layer 960, the fourth p-type host 962 and the fourth n-type host 964 may have the same weight %. With respect to 100 parts by weight of the second fluorescent compound 968, each of the fourth p-type host 962 and the fourth n-type host 964 may have a part by weight of 5000 to 15000, and the fourth phosphorescent dopant 966 may have a part by weight of 1000 to 3000.

For example, in the fourth blue emitting layer 960, a summation of a weight % of the fourth p-type host 962, a weight % of the fourth n-type host 964, a weight % of the fourth phosphorescent compound 966 and a weight % of the second fluorescent compound 968 may be 100%.

In FIG. 9, each of the first and second blue EMLs 910 and 940 has a double-layered structure. Alternatively, one of the first and second blue EMLs 910 and 940 may have a double-layered structure, and the other one of the first and second blue EMLs 910 and 940 may have a single-layered structure.

For example, the blue EML having a single-layered structure may include a blue host and a blue dopant (e.g., an emitter). The blue EML may further include an auxiliary dopant (or an auxiliary host). In the blue EML having a single-layered structure, a weight % of the blue dopant may be smaller than that of each of the blue host and the auxiliary dopant.

For example, the blue host may include at least one of the compounds in Formula 12, the blue dopant may be selected from the compounds in Formula 13, and the auxiliary dopant may be selected from the compounds in Formula 14.

The blue EML having a single-layered structure may be one of a fluorescent emitting layer, a phosphor-sensitized fluorescence (PSF) emitting layer and a hyper-fluorescence emitting layer.

The organic light emitting layer 820 of the OLED D7 includes the first emitting part ST1 including the first blue EML 910, the second emitting part ST2 including the second blue EML 940 and the third emitting part ST3 including the red, yellow-green and green EMLs 970a, 970c and 970b so that the OLED D7 has a tandem structure.

The first blue EML 910 includes the first blue emitting layer 920, which includes the first p-type host 922, the first n-type host 924 and the first phosphorescent compound 926, and the second blue emitting layer 930, which includes the second p-type host 932, the second n-type host 934, the second phosphorescent compound 936 and the first fluorescent compound 938. Each of the first and second p-type hosts 922 and 932 is a compound represented by Formula 1, and each of the first and second n-type hosts 924 and 934 is a compound represented by Formula 3. Each of the first and second phosphorescent compounds 926 and 936 is represented by Formula 5, and the first fluorescent compound 938 is represented by Formula 7.

The second blue EML 940 includes the third blue emitting layer 950, which includes the third p-type host 952, the third n-type host 954 and the third phosphorescent compound 956, and the fourth blue emitting layer 960, which includes the fourth p-type host 962, the fourth n-type host 964, the fourth phosphorescent compound 966 and the second fluorescent compound 968. Each of the third and fourth p-type hosts 952 and 962 is a compound represented by Formula 1, and each of the third and fourth n-type hosts 954 and 964 is a compound represented by Formula 3. Each of the third and fourth phosphorescent compounds 956 and 966 is represented by Formula 5, and the second fluorescent compound 968 is represented by Formula 7.

Accordingly, the OLED D7 and the organic light emitting display device 700 of the present disclosure have advantages in the emitting efficiency and the color purity.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting diode, comprising:
a first electrode as an anode;
a second electrode as a cathode facing the first electrode; and
a first emitting part including a first blue emitting material layer and positioned between the first and second electrodes, the first blue emitting material layer including a first blue emitting layer and a second blue emitting layer,
wherein the second blue emitting layer is positioned between the first blue emitting layer and the second electrode,
wherein the first blue emitting layer includes a first phosphorescent compound, and the second blue emitting layer includes a second phosphorescent compound and a first fluorescent compound,
wherein each of the first and second phosphorescent compounds is represented by Formula 5: 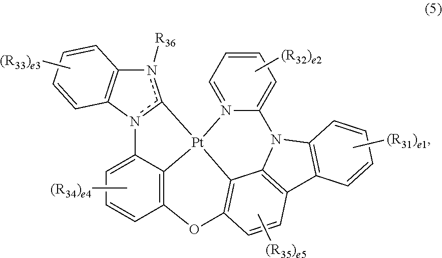
wherein in Formula 5,
each of e1, e2 and e3 is independently an integer of 0 to 4, e4 is an integer of 0 to 3, e5 is an integer of 0 to 2, and
each of R₃₁ to R₃₆ is independently selected from the group consisting of deuterium, halogen, cyano, a substituted or unsubstituted C1 to C20 alkyl group, a substituted or unsubstituted C3 to C20 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C60 heteroaryl group,
wherein the first fluorescent compound is represented by Formula 7: 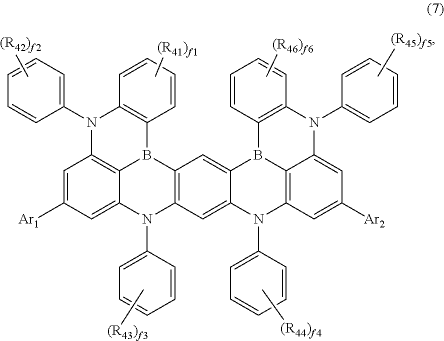
wherein in Formula 7,
each of f1 and f6 is independently an integer of 0 to 4, each of f2 to f5 is independently an integer of 0 to 5,
each of R₄₁ to R₄₆ is independently selected from the group consisting of deuterium, a substituted or unsubstituted C1 to C10 alkyl group, a substituted or unsubstituted C1 to C10 alkoxy group, a substituted or unsubstituted C6 to C30 arylsilyl group, a substituted or unsubstituted C6 to C30 arylamino group, a substituted or unsubstituted C6 to C30 aryl group and a substituted or unsubstituted C3 to C60 heteroaryl group, and
each of Ar₁ and Ar₂ is independently selected from the group consisting of a substituted or unsubstituted C6 to C30 arylamino group, a substituted or unsubstituted C6 to C30 aryl group and a substituted or unsubstituted C3 to C60 heteroaryl group.

2. The organic light emitting diode according to claim 1, wherein each of the first and the second phosphorescent compounds is independently selected from compounds PD-1 to PD13:

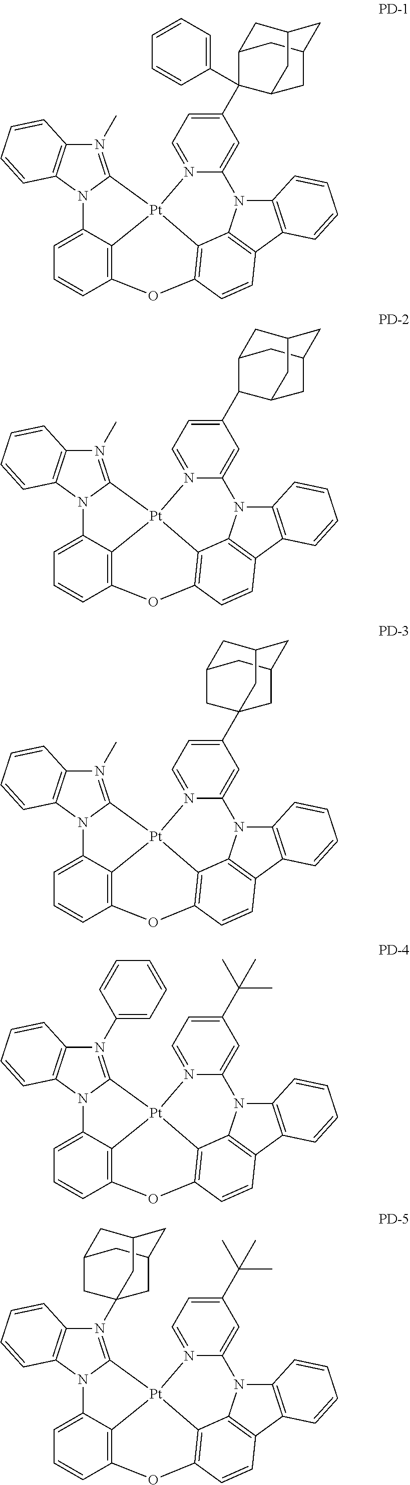

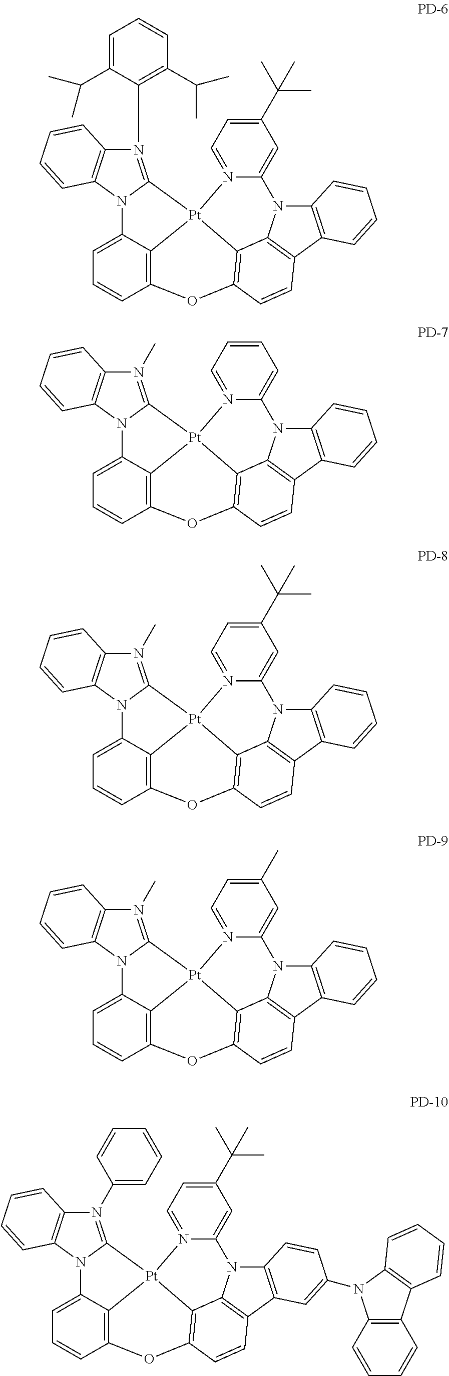

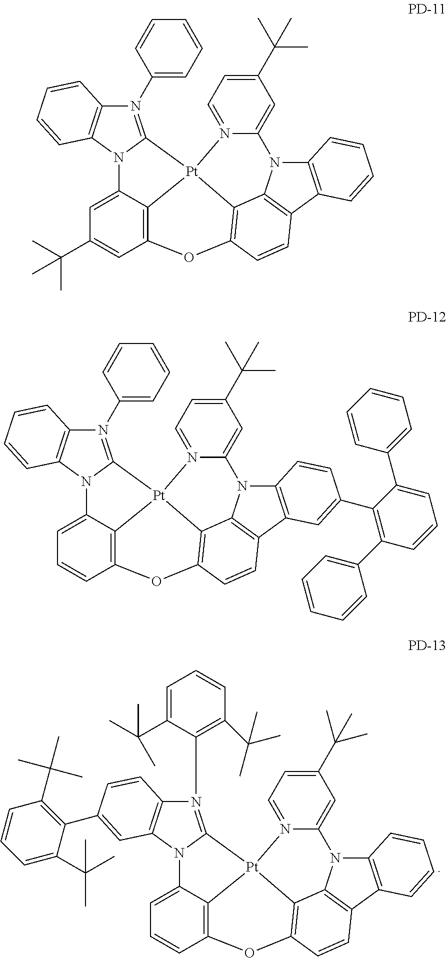

3. The organic light emitting diode according to claim 1, wherein the first fluorescent compound is one of compounds FD-1 to FD-12:

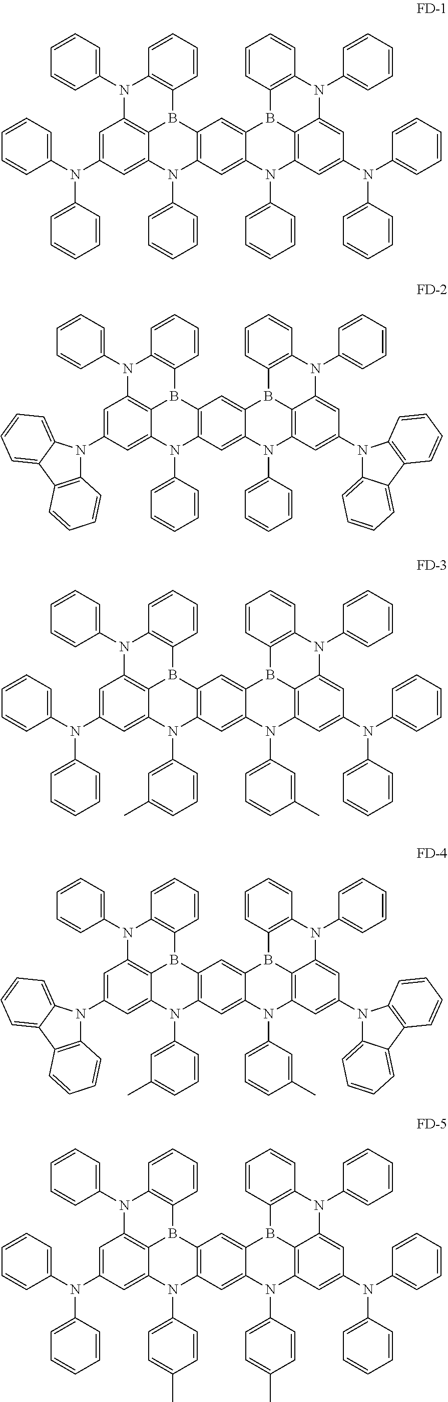

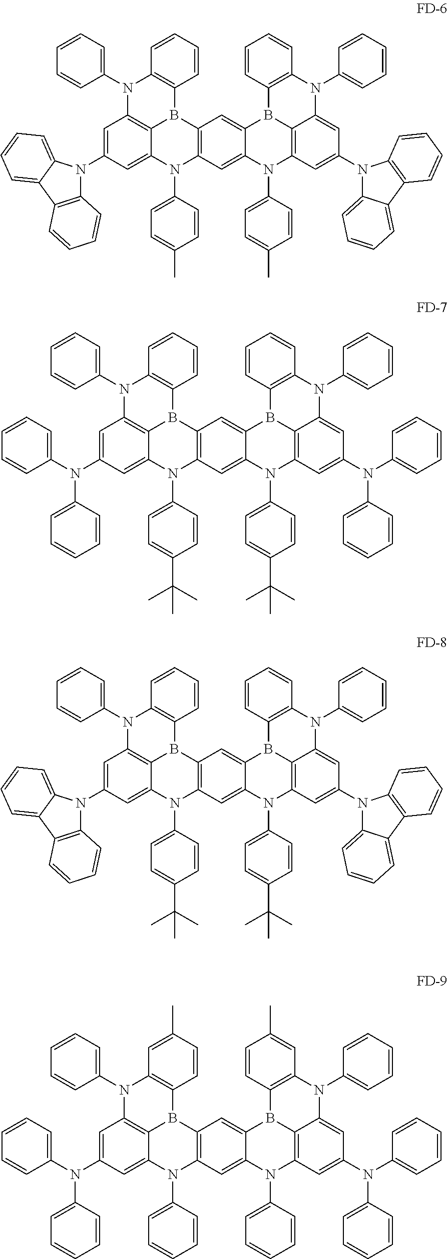

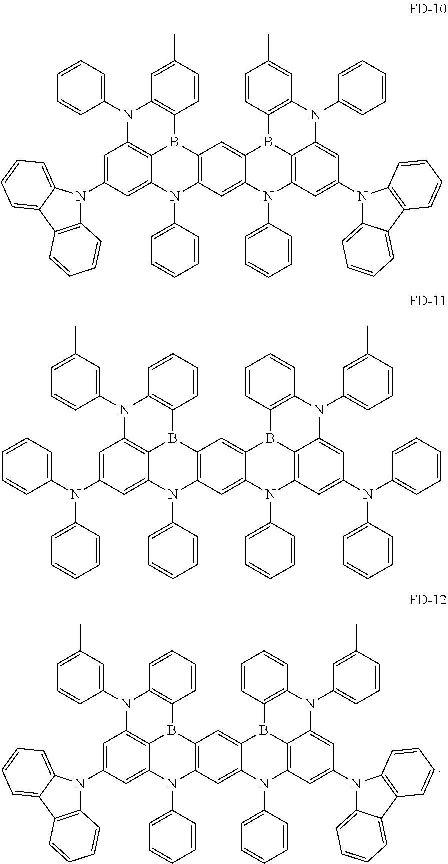 [SMILES: Cc1ccc2c(c1)N(c1ccccc1)c1cc(-n3c4ccccc4c4ccccc43)cc3c1B2c1cc2c(cc1N3c1ccccc1)N(c1ccccc1)c1cc(-n3c4ccccc4c4ccccc43)cc3c1B2c1ccc(C)cc1N3c1ccccc1 ; Cc1cccc(N2c3ccccc3B3c4cc5c(cc4N(c4ccccc4)c4cc(N(c6ccccc6)c6ccccc6)cc2c43)N(c2ccccc2)c2cc(N(c3ccccc3)c3ccccc3)cc3c2B5c2ccccc2N3c2cccc(C)c2)c1 ; Cc1cccc(N2c3ccccc3B3c4cc5c(cc4N(c4ccccc4)c4cc(-n6c7ccccc7c7ccccc76)cc2c43)N(c2ccccc2)c2cc(-n3c4ccccc4c4ccccc43)cc3c2B5c2ccccc2N3c2cccc(C)c2)c1]

4. The organic light emitting diode according to claim 1, wherein the first blue emitting layer further includes a first p-type host and a first n-type host, and the second blue emitting layer further includes a second p-type host and a second n-type host.

5. The organic light emitting diode according to claim 4, wherein each of the first p-type host and the second p-type host is represented by Formula 1: 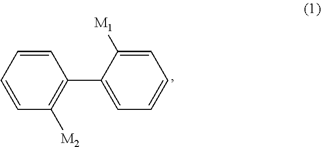
wherein in Formula 1, each of M₁ and M₂ is independently selected from Formula 1a, Formula 1b and Formula 1c: 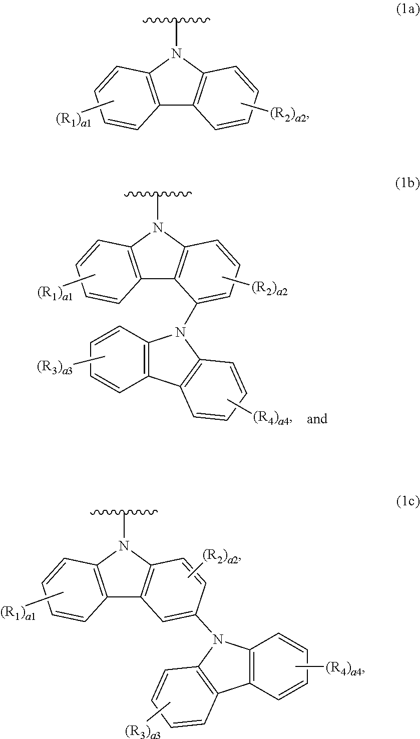
wherein in Formulas 1a, 1b and 1c, each of a1, a3 and a4 is independently an integer of 0 to 4, a2 is an integer of 0 to 3, and
each of R₁ to R₄ is independently selected from the group consisting of a substituted or unsubstituted C6 to C30 arylsilyl group, a substituted or unsubstituted C6 to C30 aryl group and a substituted or unsubstituted C3 to C60 heteroaryl group.

6. The organic light emitting diode according to claim 5, wherein each of the first p-type host and the second p-type host is independently selected from compounds PH-1 to PH-11:

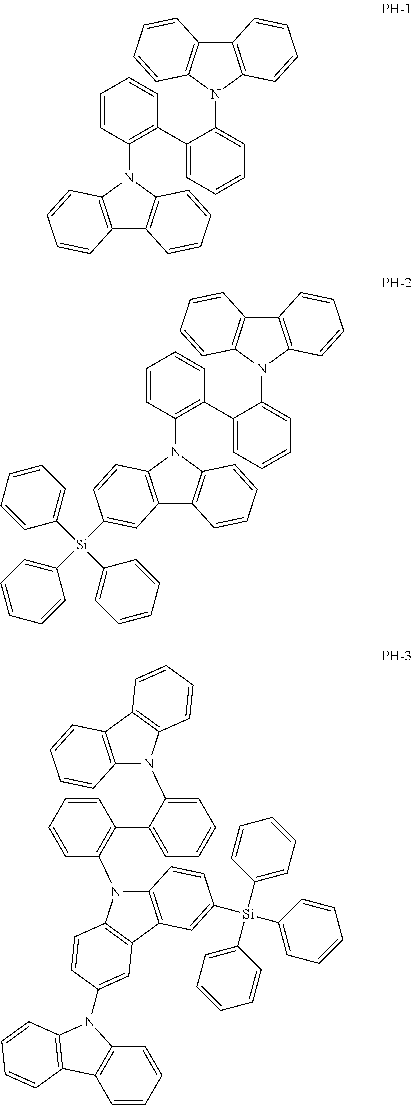 [SMILES: c1ccc(-n2c3ccccc3c3ccccc32)c(-c2ccccc2-n2c3ccccc3c3ccccc32)c1 ; c1ccc([Si](c2ccccc2)(c2ccccc2)c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2cc(-n4c5ccccc5c5ccccc54)ccc2n3-c2ccccc2-c2ccccc2-n2c3ccccc3c3ccccc32)cc1]

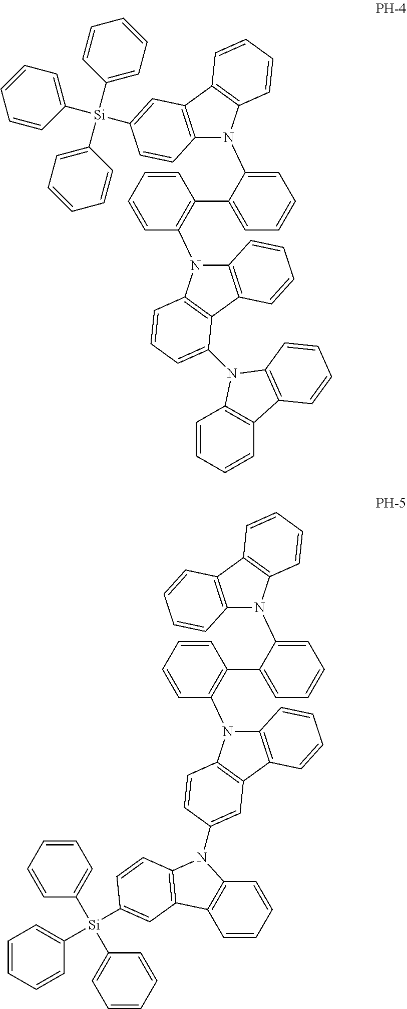 [SMILES: c1ccc([Si](c2ccccc2)(c2ccccc2)c2ccc3c(c2)c2ccccc2n3-c2ccccc2-c2ccccc2-n2c3ccccc3c3c(-n4c5ccccc5c5ccccc54)cccc32)cc1 ; c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1]

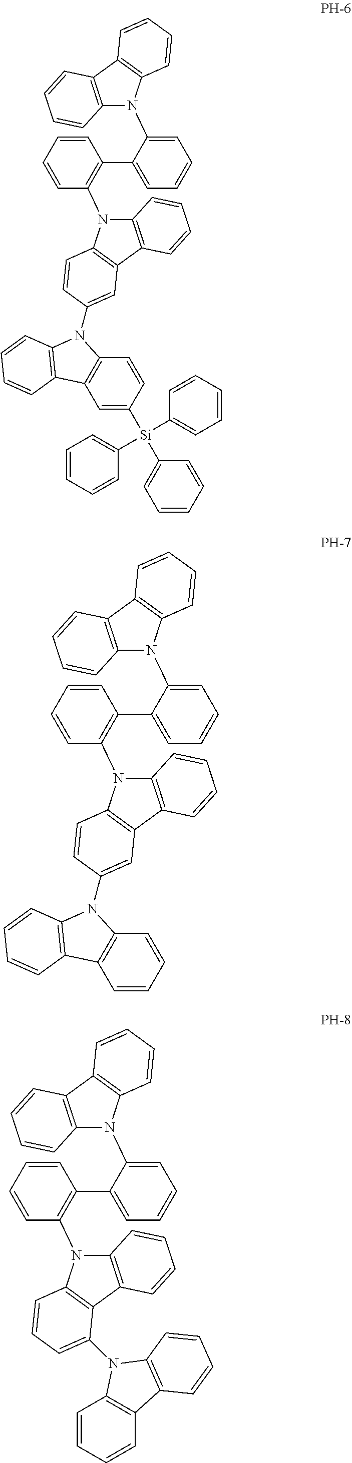

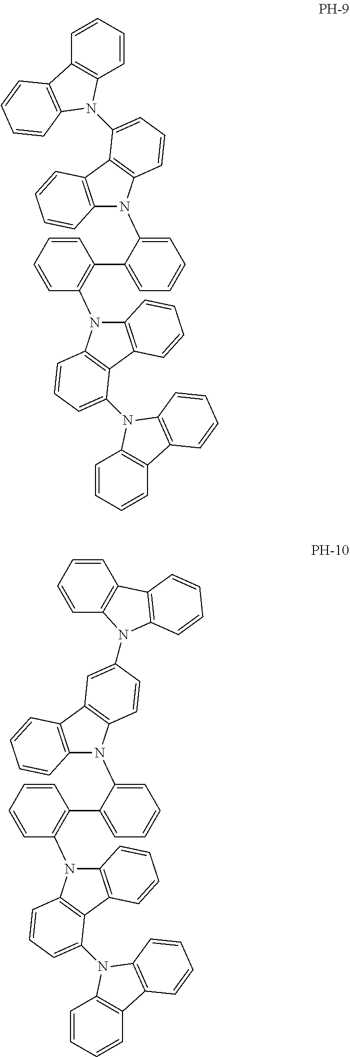 [SMILES: c1ccc(-n2c3ccccc3c3c(-n4c5ccccc5c5ccccc54)cccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1]

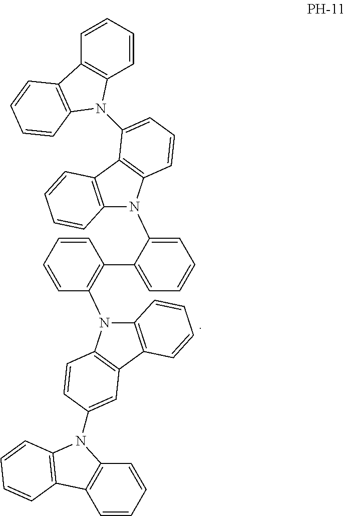 [SMILES: c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1]

7. The organic light emitting diode according to claim 4, wherein each of the first n-type host and the second n-type host is represented by Formula 3: 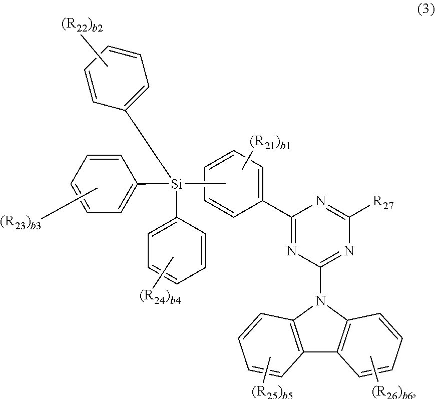
wherein in Formula 3, each of b1, b5 and b6 is independently an integer of 0 to 4, each of b2 to b4 is independently an integer of 0 to 5, and
each of R₂₁ to R₂₇ is independently selected from the group consisting of deuterium, halogen, cyano, a substituted or unsubstituted C6 to C30 arylsilyl group, a substituted or unsubstituted C1 to C10 alkyl group, a substituted or unsubstituted C6 to C30 aryl group, a substituted or unsubstituted C3 to C60 heteroaryl group, a substituted or unsubstituted C6 to C60 arylamino group.

8. The organic light emitting diode according to claim 7, wherein each of the first n-type host and the second n-type host is independently selected from compounds NH-1 to NH-6:

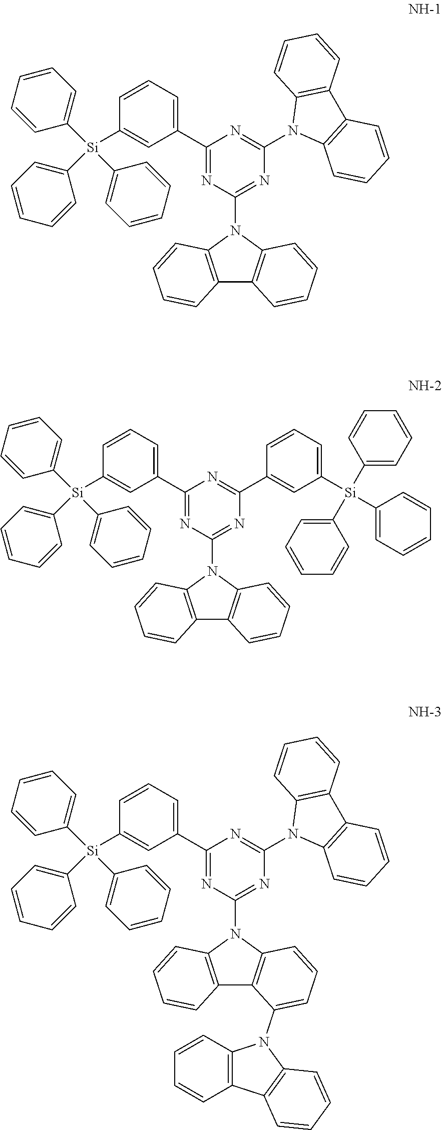 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5c(-n6c7ccccc7c7ccccc76)cccc54)n3)c2)cc1]

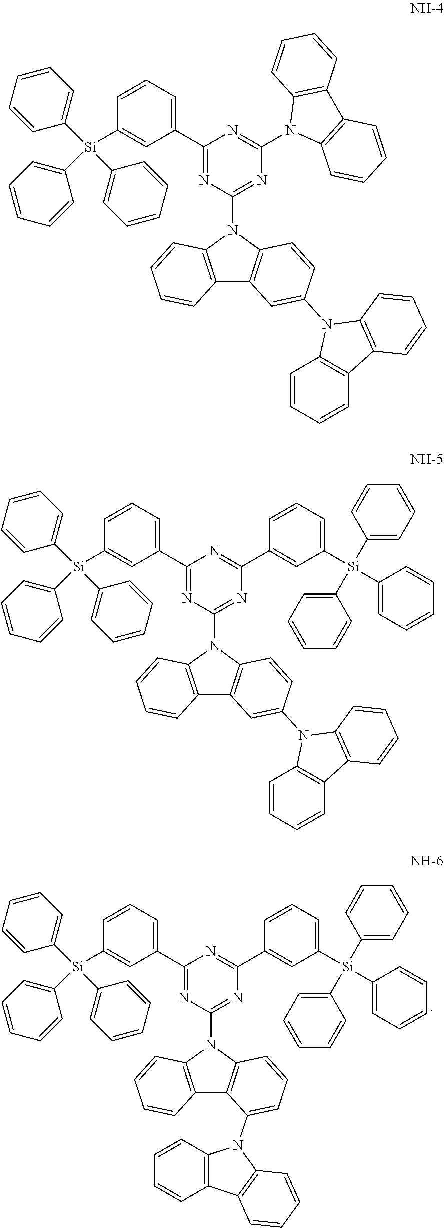 [SMILES: c1ccc([Si](c2ccccc2)(c2ccccc2)c2cccc(-c3nc(-n4c5ccccc5c5ccccc54)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5c(-n6c7ccccc7c7ccccc76)cccc54)n3)c2)cc1]

9. The organic light emitting diode according to claim 1, wherein a thickness of the second blue emitting layer is greater than a thickness of the first blue emitting layer.

10. The organic light emitting diode according to claim 1, further comprising:
a second emitting part including a second blue emitting material layer and positioned between the first emitting part and the second electrode.

11. The organic light emitting diode according to claim 10, wherein the second blue emitting material layer includes a third blue emitting layer and a fourth blue emitting layer between the third blue emitting layer and the second electrode,
wherein the third blue emitting layer includes a third phosphorescent compound, and the fourth blue emitting layer includes a fourth phosphorescent compound and a second fluorescent compound, and
wherein each of the third and fourth phosphorescent compounds is represented by Formula 5, and the second fluorescent compound is represented by Formula 7.

12. The organic light emitting diode according to claim 11, wherein the third blue emitting layer further includes a third p-type host and a third n-type host, and the fourth blue emitting layer includes a fourth p-type host and a fourth n-type host.

13. The organic light emitting diode according to claim 12, wherein each of the third p-type host and the fourth p-type host is represented by Formula 1: 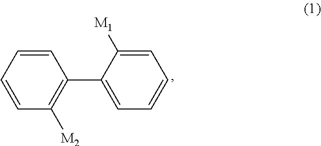
wherein in Formula 1, each of M₁ and M₂ is independently selected from Formula 1a, Formula 1b and Formula 1c: 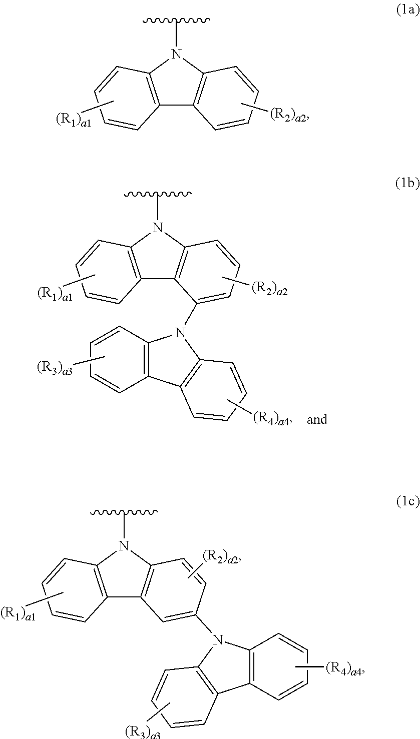
wherein in Formulas 1a, 1b and 1c, each of a1, a3 and a4 is independently an integer of 0 to 4, a2 is an integer of 0 to 3, and
each of R₁ to R₄ is independently selected from the group consisting of a substituted or unsubstituted C6 to C30 arylsilyl group, a substituted or unsubstituted C6 to C30 aryl group and a substituted or unsubstituted C3 to C60 heteroaryl group.

14. The organic light emitting diode according to claim 12, wherein each of the third n-type host and the fourth n-type host is represented by Formula 3: 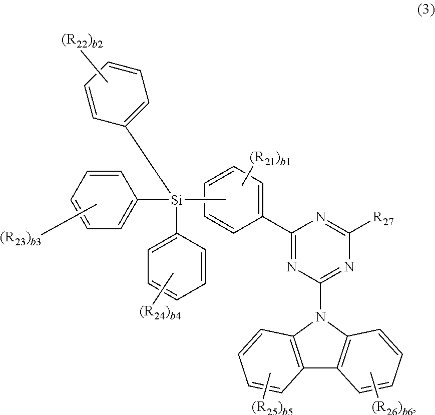
wherein in Formula 3, each of b1, b5 and b6 is independently an integer of 0 to 4, each of b2 to b4 is independently an integer of 0 to 5, and
each of R₂₁ to R₂₇ is independently selected from the group consisting of deuterium, halogen, cyano, a substituted or unsubstituted C6 to C30 arylsilyl group, a substituted or unsubstituted C1 to C10 alkyl group, a substituted or unsubstituted C6 to C30 aryl group, a substituted or unsubstituted C3 to C60 heteroaryl group, a substituted or unsubstituted C6 to C60 arylamino group

15. The organic light emitting diode according to claim 11, wherein a thickness of the fourth blue emitting layer is greater than a thickness of the third blue emitting layer.

16. The organic light emitting diode according to claim 10, further comprising:
a third emitting part including a red emitting material layer and a green emitting material layer and positioned between the first and second emitting parts.

17. The organic light emitting diode according to claim 16, wherein the third emitting part further includes a yellow-green emitting material layer between the red and green emitting material layer.

18. The organic light emitting diode according to claim 1, further comprising:
an additional emitting part including an additional blue emitting material layer and positioned between the first emitting part and the second electrode or positioned between the first emitting part and the first electrode.

19. The organic light emitting diode according to claim 18, wherein the additional blue emitting material layer has a single-layered structure including a blue host and a blue dopant.

20. An organic light emitting diode, comprising:
an anode;
a cathode facing the anode; and
an organic light emitting layer positioned between the anode and the cathode and including a blue emitting material layer,
wherein the blue emitting material layer includes a first blue emitting layer and a second blue emitting layer which contacts the first blue emitting layer and is disposed between the first blue emitting layer and the cathode,
wherein the first blue emitting layer is a phosphorescent emitting layer including a first phosphorescent compound, and the second blue emitting layer is a phosphor-sensitized fluorescence emitting layer including a second phosphorescent compound and a fluorescent compound, and
wherein a thickness ratio of the second blue emitting layer to the first blue emitting layer is in a range of 1:4 to 4:1.

21. The organic light emitting diode according to claim 20, wherein a thickness ratio of the second blue emitting layer to the first blue emitting layer is in a range of 1:3 to 3:1.

22. The organic light emitting diode according to claim 20, wherein each of the first and second phosphorescent compounds is represented by Formula 5: 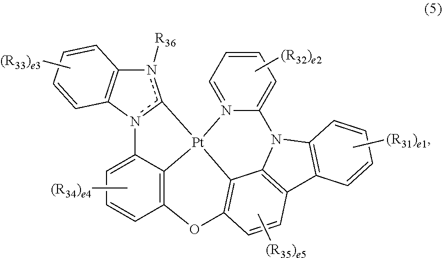
wherein in Formula 5,
each of e1, e2 and e3 is independently an integer of 0 to 4, e4 is an integer of 0 to 3, e5 is an integer of 0 to 2, and
each of R₃₁ to R₃₆ is independently selected from the group consisting of deuterium, halogen, cyano, a substituted or unsubstituted C1 to C20 alkyl group, a substituted or unsubstituted C3 to C20 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C60 heteroaryl group.

23. The organic light emitting diode according to claim 20, wherein the fluorescent compound is represented by Formula 7: 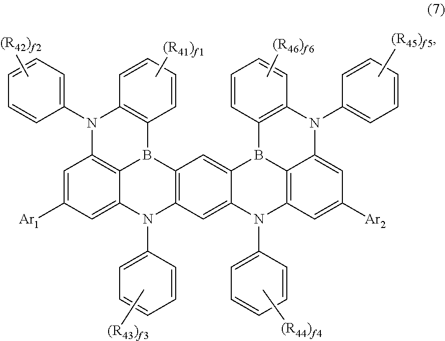
wherein in Formula 7,
each of f1 and f6 is independently an integer of 0 to 4, each of f2 to f5 is independently an integer of 0 to 5,
each of R₄₁ to R₄₆ is independently selected from the group consisting of deuterium, a substituted or unsubstituted C1 to C10 alkyl group, a substituted or unsubstituted C1 to C10 alkoxy group, a substituted or unsubstituted C6 to C30 arylsilyl group, a substituted or unsubstituted C6 to C30 arylamino group, a substituted or unsubstituted C6 to C30 aryl group and a substituted or unsubstituted C3 to C60 heteroaryl group, and
each of Ar₁ and Ar₂ is independently selected from the group consisting of a substituted or unsubstituted C6 to C30 arylamino group, a substituted or unsubstituted C6 to C30 aryl group and a substituted or unsubstituted C3 to C60 heteroaryl group.

24. An organic light emitting device, comprising:
a substrate;
the organic light emitting diode according to claim 1 and disposed over the substrate; and
an encapsulation layer covering the organic light emitting diode.

25. The organic light emitting device according to claim 24, further comprising:
a color filter layer positioned between the substrate and the organic light emitting diode or on the encapsulation layer.
